(19) United States
(12) Patent Application Publication
(10) Pub. No.: US 2009/0289270 A1
(43) Pub. Date: Nov. 26, 2009

(54) GROUP III NITRIDE SEMICONDUCTOR MULTILAYER STRUCTURE AND PRODUCTION METHOD THEREOF

(75) Inventors: Kenzo HANAWA, Ichihara-shi (JP); Yasunori YOKOYAMA, Ichihara-shi (JP); Yasumasa SASAKI, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: SHOWA DENKO K.K., Tokyo (JP)

(21) Appl. No.: 12/468,644

(22) Filed: May 19, 2009

Related U.S. Application Data
(60) Provisional application No. 61/090,562, filed on Aug. 20, 2008.

(30) Foreign Application Priority Data
May 23, 2008 (JP) 2008-135939

(51) Int. Cl. H01L 33/00; H01L 29/20; C23C 14/00

(52) U.S. Cl. 257/98; 257/615; 204/192.25; 257/103; 257/E33.025; 257/E29.089; 257/E33.061

(57) ABSTRACT

According to the invention it is possible to obtain a flat AlN crystal film seed layer with a high degree of crystallinity, and particularly, a flat AlN crystal film seed layer that is homogeneous throughout can be used even with large substrates having diameters of 100 mm and greater, in order to obtain highly crystalline GaN-based thin-films for highly reliable, high-luminance LED elements and the like. The invention relates to a Group III nitride semiconductor multilayer structure obtained by layering an n-type semiconductor layer, composed of a Group III nitride semiconductor, a luminescent layer and a p-type semiconductor layer, on a sapphire substrate, the Group III nitride semiconductor multilayer structure having an AlN crystal film that is accumulated as the seed layer by sputtering on the sapphire substrate surface, and the AlN crystal film having a grain boundary spacing of 200 nm or greater. The arithmetic mean surface roughness (Ra) of the AlN crystal film surface is preferably no greater than 2 angstrom. The oxygen content of the AlN crystal film is preferably no greater than 5 atomic percent.

### CROSS-REFERENCES TO RELATED APPLICATIONS

This application is an application filed under 35 U.S.C. §111(a) claiming benefit pursuant to 35 U.S.C. § of the filing date of provisional Application No. 61/090,562 filed Sep. 8, 2008 pursuant to 35 U.S.C. §111(b).

### FIELD OF THE INVENTION

The present invention relates to a Group III nitride semiconductor multilayer structure and to a production method thereof.

### BACKGROUND OF THE INVENTION

The Group III nitride semiconductors GaN, AlN, InGaN and AlGaN are extremely difficult to grow into large-sized bulk single crystals, and therefore heteroepitaxial growth has generally been employed using sapphire as the substrate. However, sapphire and the aforementioned Group III nitride semiconductors have a lattice mismatch of 11-23% and a thermal expansion coefficient difference of approximately 2×10⁻⁶/° C. Also, because of the differences in chemical properties, Group III nitride semiconductor epitaxial films directly grown on sapphire only partially inherit the single crystal nature of the substrate and grow three-dimensionally, making it extremely difficult to maintain a flat surface form. Among the required properties for substrates used for growth of GaN single crystal films, they must have heat resistance up to 1200° C. and must not react with NH₃ at that temperature. Therefore, only sapphire and SiC are currently available as substrates that permit production at practical cost. Sapphire is overwhelmingly advantageous from a cost comparison viewpoint, and over 90% of the GaN-based light emitting diodes (LED) actually produced in the world employ sapphire substrates. However, because sapphire and GaN have different lattice constants and different thermal expansion coefficients, while their chemical properties are also different, it is considered impossible to directly grow GaN single crystals. Consequently, although vast improvements have been achieved with GaN-based light emitting diodes formed on sapphire substrates as a result of various modifications, they include interior defects at a rather high density, and hence the enhancements to luminous efficiency and element lifespan have been limited.

In general, the following two different strategies may be considered to obtain single-crystal films with satisfactory crystallinity by heteroepitaxial growth with large lattice mismatches.

(i) Growth may be conducted through a material with physical constants intermediate between the substrate and the epitaxial film to improve the quality of the epitaxial film. That is, a thin-film having intermediate properties such as lattice constant, chemical properties and thermal expansion coefficient is sandwiched between them. In this case, a single crystal thin-film must be inserted since it is desired for the properties of the single crystal of the substrate to be directly inherited as a single crystal.
(ii) A polycrystalline or amorphous film with the same properties as the desired single crystal thin-film is inserted. Such films are usually formed at temperatures lower than the single crystal growth temperature (Japanese Examined Patent Publication SHO No. 62-29397). Epitaxial growth of SOS (Silicon On Sapphire substrate) is a notable example. Success has also been achieved with low-temperature buffer layers using GaN on sapphire substrates. The mechanism is based on inhibiting grain boundary formation due to high nucleation of GaN on the buffer layer and the fact that only crystal grains with well-ordered crystal orientation are selectively grown and united therein, while also utilizing the high growth on the buffer layer in the lateral growth direction to achieve flattening (Akazaki, I., Journal of the Japan Crystal Growth Academy, Vol. 13, No. 4, 1986, pp 218-225; Vol. 15 No. 3-4, 1988, pp 334-342; and Vol. 20, No. 4, 1993, pp 346-354).

First, strategy (i) considers that growth may be conducted through a material with physical constants intermediate between the substrate and the epitaxial film to improve the quality of the epitaxial film. Thus, growth via an AlN layer is considered effective for growing a GaN layer on sapphire. This is because AlN has a lattice constant and thermal expansion coefficient that are intermediate between sapphire and GaN, such that lattice mismatches and thermal distortion are efficiently moderated. In addition, the similar chemical properties of AlN and GaN result in low interfacial energy between them. This can also be understood from a different viewpoint. Sapphire, or Al₂O₃, is an oxide, and the most chemically similar nitride is AlN which also contains Al. Lattice mismatching is relatively high at 11%, but the common presence of Al helps facilitate growth of AlN single crystals. Moreover, since AlN is the only compound that mixes completely with GaN in solid solution, its chemical properties are the most similar and lattice mismatches are only at 2%. Consequently, even though it is difficult to grow Al₂O₃/GaN directly, inserting AlN to form Al₂O₃/AlN/GaN allows growth of a GaN single crystal that inherits the crystallinity of sapphire (Al₂O₃). Thus, if a flat AlN layer could be formed directly as a single crystal, it would be possible to vastly improve the GaN film quality of heteroepitaxial films grown thereon.

The following three processes are known as AlN film-forming processes designed for this purpose.

I. A process in which a sapphire substrate is heat treated in a nitrogen source gas atmosphere such as NH₃, N₂H₂ or an organic amine to convert the substrate surface to single crystal AlN (Japanese Examined Patent Publication HEI No. 7-54806) or a chemical vapor deposition process in which Al is vapor deposited in a NH₃ or N₂H₂ atmosphere Japanese Examined Patent Publication SHO No. 59-48796).
II. A process in which an aluminum source gas such as organic aluminum, halogenated aluminum or metal aluminum vapor and a nitrogen source gas are supplied onto a sapphire substrate kept at high temperature allowing single crystal growth of AlN, and a single crystal AlN layer is accumulated (Japanese Unexamined Patent Publication HEI No. 9-64477), which process usually requires a high temperature of about 1300° C.
III. A process in which an aluminum source gas and a nitrogen source gas are supplied at a low temperature of 500-1000° C. and a polycrystalline or amorphous AlN layer is accumulated to several 100-1000 angstrom, after which annealing is performed at a higher temperature to form a single crystal (Japanese Examined Patent Publication HEI No. 4-15200, Japanese Unexamined Patent Publication HEI No. 5-41541).

For surface nitriding in the process of I. above, a nitride layer of several tens of angstroms can be formed with satisfactory reproducibility, and because the single crystal AlN layer has gradient compositional variation, lattice mismatches are effectively moderated in a region of only several tens of angstroms. Chemical vapor deposition requires an ultrahigh vacuum of 10⁻⁸ Torr, and Al vapor is reacted with NH₃ or N₂H₂ on the substrate at a high temperature of 1000-1200° C. However, the AlN layer formed by this process does not undergo homogeneous nitriding reaction, and therefore surface roughness on the order of 10 angstrom easily forms. When epitaxial growth is carried out on a surface-roughened AlN layer, the irregularities are exaggerated with increasing film thickness, such that a flat surface shape cannot be obtained.

On the other hand, an AlN layer is formed in process II by film growth at high temperature, and therefore growth nuclei cannot be simultaneously generated in a uniform manner and continued generation of nuclei makes it impossible to avoid three-dimensional growth. Ito et al. have written that a smooth GaN crystal surface cannot be obtained without the function of a mechanism used for low temperature buffers, whereby the NH₃ flow rate is reduced to an absolute minimum even during AlN growth high temperature, to inhibit single crystal growth and simultaneously produce uniform fine polycrystals while promoting lateral growth to form a smooth surface (J. Crystal Growth, 205 (1999) pp 20-24).

Thus, while a single crystal AlN layer formed by process I or II improves the crystallinity of epitaxial films grown thereover and has a definite function that enhances optical characteristics such as PL (photoluminescence), three-dimensional growth is promoted creating an irregular surface, and it is therefore difficult to obtain an epiwafer suitable for fabrication of LED devices that are reliable under a flow of current.

Flat amorphous layers can be formed by the process of III since an AlN film is accumulated at low temperature which does not permit three-dimensional growth. However, when annealing is performed to complete single crystal formation, minute differences in orientation are produced between the sections that crystallize first and the sections that crystallize later, such that the surface begins to become disordered. Irregularities continue to form as the GaN epitaxial film grows thereover.

As explained above, processes that employ single crystal AlN seed layers with intermediate physical constants for heteroepitaxial growth of a GaN single crystal on a sapphire substrate have been studied in the past, but at the time of this writing the field has been virtually resigned to the fact that surface flatness cannot be maintained.

Currently, therefore, buffer layers are being employed in the context of process (ii) instead of (i) above. For use as a buffer layer, there is no point in having intermediate physical constants and it is the basic practice to use a microcrystalline or amorphous thin-film with the same composition as the single crystal that is to be grown. Consequently, the most widely employed processes are low-temperature buffer processes in which the buffer used is a layer obtained by forming a GaN film at low temperatures of near 500° C.

On the other hand, sputtering has long been employed as a process for obtaining AlN with a uniform film thickness. The following report has been published by A. J. Shuskus et al. (Applied Physics Letters, Vol. 24, No. 4 (1974) pp 155-156). Specifically, it is stated that a single crystal thin-film was successfully formed, based on reflective electron beam analysis, by subjecting a high purity Al target to RF discharge in NH₃ gas using a reactor capable of producing a vacuum of 10⁻⁸ Torr, to form an AlN film on a (0001) sapphire substrate at 1200° C. However, the obtained AlN film exhibits only one pattern in reflection electron diffraction, while no columnar crystal grain boundary is present and nothing is mentioned regarding the surface properties. Later, C. R. Aita et al. formed an AlN thin-film on single crystal Si at room temperature by discharge of a mixed gas of Ar and N₂ with a high purity Al target, and examined the discharge conditions and formed film quality in detail (J. Appl. Phys. Vol. 53, No. 3 (1982) pp 1807-1809, J. Vac. Sci. Technol. A Vol. 1, No. 2 (1983) pp 403-406). Also, W. J. Meng et al. reported on a film-forming experiment on Si(111), Si(100) substrates under the same conditions with a temperature of above 600° C., each forming an AlN thin-film with an extremely fine smooth polycrystalline surface oriented in alignment with the C-plane (J. Appl. Phys. Vol. 75, No. 7 (1994) pp 3446-3455). Many doubts were later raised in regard to its potential for application as a compound semiconductor, in light of the AlN energy gap of 6.2 eV, and it has not been actually employed.

Plasma generation produces a high energy electron flow which, when driven into crystals, creates defects in the crystals known as “plasma damage”. Therefore, sputtering has not been actively used for semiconductors that require thin-film crystals with minimally low defects. Still, the fact that sputtering is a highly superior method for forming thin-films of several tens to several hundreds of angstroms in a reproducible manner has become evident through its proven performance in allowing stable mass production of thin-films with high functionality as multilayer thin-films, in Si semiconductor wiring processes and in the field of hard disk media or heads, and much active research has been carried out on sputtering processes. AlN film formation by sputtering produces amorphous or polycrystalline films in most cases, and very few reports of single crystal film formation exist. Most notably, single crystals are damaged when exposed to plasma, as implied by the term “plasma damage”. Thus, while sputtering is a highly advantageous process for formation of films while maintaining substrate flatness, it is seldom considered as a process for increased crystallinity.

On the other hand, the low-temperature buffer approach is based on the fact that flat single crystals can be formed by simultaneous generation of polycrystal nuclei in a homogeneous and fine structural fashion, resulting in integration only of crystals with aligned orientation, and utilizing lateral growth. It is therefore necessary to form a homogeneous thin-film which is either polycrystalline or amorphous. One approach of note is to use AlN in sputtering for formation of a low-temperature buffer. An amorphous AlN or GaN film is formed by reaction sputtering using an Al or Ga target, and removed from the apparatus before growing GaN by MOCVD (Japanese Unexamined Patent Publication No. 2000-286202, Japanese Unexamined Patent Publication No. 2001-94150, Japanese Unexamined Patent Publication SHO No. 60-173829). Formation of AlN buffer layers on sapphire substrates by sputtering has thus been studied, but such AlN layers comprise columnar crystals.

In 1972, Cuomo et al. succeeded in forming a polycrystalline thin-film with aligned GaN by reaction sputtering using a Ga target on a sapphire substrate (Appl. Phys. Lett., Vol. 20, No. 2 (1972), pp 71-72, Japanese Unexamined Patent Publication SHO No. 48-40699), and the technique was developed as a proposed method for forming a buffer layer and ground layer by sputtering (U.S. Pat. No. 6,692,568, U.S. Pat. No. 6,784,085, Japanese Patent Public Inspection 2004-523450). By generating numerous columnar crystals on a substrate and including modifications to the apparatus or varying the conditions such as the ratio of Ar and N₂ and the discharge power, a single crystal GaN thin-film was obtained on the columnar crystals using lateral growth whereby only portions with essentially aligned crystal orientation were integrated in the columnar crystals (for example, see FIG. 4 of U.S. Pat. No. 6,692,568).

As mentioned above, the two different methods for heteroepitaxial growth of GaN-based semiconductors on sapphire substrates are (i) sandwiching a single crystal seed layer with intermediate physical and chemical properties, and (ii) forming a buffer layer by simultaneously generating nuclei in a homogeneous and fine structural fashion for a polycrystalline or amorphous film with the same composition as the desired single crystal, to accomplish integrated growth only of crystals with aligned orientation, and method (ii) has been widely adopted. Sputtering has been considered and widely studied as a method of forming thin-films while maintaining flatness on sapphire substrates. However, while it is effective for polycrystalline or amorphous buffer layers, it has not been used for flat single crystal seed films. This is because sputtering has generally been assumed to be unsuitable as a method for forming single crystals.

As mentioned above, the method of inserting a single crystal thin layer from the viewpoint of strategy (i) does not allow three-dimensional growth to be easily prevented in the context of prior art processes, and even with a sapphire substrate surface roughness of about Ra=0.8A the thin-films formed thereover have Ra values of 10 angstrom and greater. When a low-temperature buffer layer is used, columnar crystals appear in some sections when the temperature is raised for formation of the GaN-based semiconductor film, thus also resulting in a surface flatness with an Ra value of 10 angstrom or greater.

In contrast, the present invention differs from a low-temperature buffer layer according to the generally employed method (ii), in that its purpose is to obtain a GaN-based crystal from the viewpoint of method (i) which is not being employed at the current time. The almost total failure of the conventional methods from the viewpoint of (i) is due to the fact that surface flatness has been significantly rougher on the formed AlN thin-films compared to the sapphire wafer surfaces.

With insertion of an AlN or GaN buffer layer because GaN does not grow directly on sapphire crystals as explained above, crystal anomalies have been reduced and highly superior GaN crystal growth has been successfully achieved for improvement to a level suitable to withstand practical LED luminescent intensity. As a result, LEDs employing GaN-based crystals have been employed in backlights for liquid crystal displays in cellular phones, leading to their increased demand at a rate of over 50% per year. In recent years, LED backlights have come to be employed in similar liquid crystal displays, as backlights for personal computer monitors and TVs. It has since become known that sufficient luminous efficiency and reliability cannot be achieved with conventional crystallinity, and demand for higher crystallinity is therefore increasing. The following two methods have been used for heteroepitaxial growth. The first is a method of inserting a single crystal seed layer having intermediate physical and chemical properties, and the second is a method of using a buffer layer whereby a polycrystalline or amorphous substance with the same composition as the single crystal is used for simultaneous generation of nuclei in a homogeneous and fine structural fashion, integrating the crystals with matching orientation in the lateral direction. The method using a low-temperature buffer is currently the most commonly employed for GaN-based semiconductors. When a buffer layer is inserted, however, the regularly ordered arrangement of atoms in the single crystal of the substrate breaks down, while partial crystallization occurs during temperature increase to the growth temperature of the low-temperature buffer layer, thus creating regions with different levels of crystallization and impairing the flatness of the surface. It has therefore been considered extremely difficult to achieve the high degree of crystallinity required for current applications.

### SUMMARY OF THE INVENTION

It is an object of the present invention to obtain a flat AlN crystal film seed layer with a high degree of crystallinity, so that a flat AlN crystal film seed layer that is homogeneous throughout can be used even with large substrates having diameters of 100 mm and greater, in order to obtain highly crystalline GaN-based thin-films for highly reliable, high-luminance LED elements and the like.

The aforementioned object is achieved by the following aspects of the present invention.

(1) A Group III nitride semiconductor multilayer structure obtained by layering an n-type semiconductor layer, composed of a Group III nitride semiconductor, a luminescent layer and a p-type semiconductor layer, on a sapphire substrate, the Group III nitride semiconductor multilayer structure being characterized by having an AlN crystal film that is accumulated as the seed layer by sputtering on the sapphire substrate surface, the AlN crystal film having a grain boundary spacing of 200 nm or greater.
(2) The Group III nitride semiconductor multilayer structure according to (1) above, wherein the arithmetic mean surface roughness (Ra) of the AlN crystal film surface is no greater than 2 angstrom.
(3) The Group III nitride semiconductor multilayer structure according to (1) or (2) above, wherein the rocking curve half-widths in X-ray diffraction for the (0002) plane and (10-10) plane of the AlN crystal film are no greater than 100 arcsec and no greater than 1.7 degrees, respectively.
(4) The Group III nitride semiconductor multilayer structure according to any one of (1) to (3) above, wherein the oxygen content of the AlN crystal film is no greater than 5 atomic percent.
(5) The Group III nitride semiconductor multilayer structure according to any one of (1) to (4) above, wherein the sapphire substrate is a C-plane sapphire substrate.
(6) The Group III nitride semiconductor multilayer structure according to any one of (1) to (5) above, wherein the sapphire substrate has an off-angle of 0.1-0.7 degrees.
(7) The Group III nitride semiconductor multilayer structure according to (1) above, wherein the sputtering method is RF sputtering.
(8) The Group III nitride semiconductor multilayer structure according to any one of (1) to (7) above, wherein the AlN crystal film is accumulated by sputtering with the sapphire substrate situated in plasma.
(9) The Group III nitride semiconductor multilayer structure according to any one of (1) to (8) above, wherein the AlN crystal film is accumulated on the sapphire substrate surface after the sapphire substrate surface has been treated with N₂ plasma or O₂ plasma.
(10) The Group III nitride semiconductor multilayer structure according to any one of (1) to (9) above, wherein the substrate temperature during accumulation of the AlN crystal film on the sapphire substrate surface is 300-800° C.
(11) The Group III nitride semiconductor multilayer structure according to any one of (1) to (10) above, wherein the film thickness of the AlN crystal film is 10-50 nm.
(12) The Group III nitride semiconductor multilayer structure according to (11) above, wherein the film thickness of the AlN crystal film is 25-35 nm.
(13) The Group III nitride semiconductor multilayer structure according to any one of (1) to (12) above, wherein the diameter of the sapphire substrate is 100 mm or greater.
(14) The Group III nitride semiconductor multilayer structure according to any one of (1) to (13) above, wherein the rocking curve half-widths of the p-contact layer as the final p-type semiconductor layer are no greater than 60 arcsec and no greater than 250 arcsec for the (0002) plane and (10-10) plane, respectively.
(15) A light emitting device comprising a Group III nitride semiconductor multilayer structure according to any one of (1) to (14) above.
(16) The light emitting diode according to (15) above, wherein an anode is provided on the n-type semiconductor layer and a cathode is provided on the p-type semiconductor layer.
(17) A production method for a Group III nitride semiconductor multilayer structure, characterized in that, for production of a Group III nitride semiconductor multilayer structure obtained by layering an n-type semiconductor layer, composed of a Group III nitride semiconductor, a luminescent layer and a p-type semiconductor layer, on a sapphire substrate, an AlN crystal film having a grain boundary spacing of 200 nm or greater is formed as the seed layer by sputtering on the sapphire substrate surface, while controlling the oxygen content to no greater than 5 atomic percent.
(18) The production method for a Group III nitride semiconductor multilayer structure according to (17) or
(20) above, wherein the center line surface roughness (Ra) of the AlN crystal film surface is no greater than 2 angstrom.
(19) The production method for a Group III nitride semiconductor multilayer structure according to (17) or
(18) above, wherein the rocking curve half-widths in X-ray diffraction for the (0002) plane and (10-10) plane of the AlN crystal film are no greater than 100 arcsec and no greater than 1.7 degrees, respectively.
(20) The production method for a Group III nitride semiconductor multilayer structure according to any one of (17) to (19) above, wherein the sapphire substrate is a C-plane sapphire substrate.
(21) The production method for a Group III nitride semiconductor multilayer structure according to any one of (17) to (20) above, wherein the sapphire substrate has an off-angle of 0.1-0.7 degrees.
(22) The production method for a Group III nitride semiconductor multilayer structure according to (17) above, wherein the sputtering method is RF sputtering.
(23) The production method for a Group III nitride semiconductor multilayer structure according to any one of (17) to (22) above, wherein the AlN crystal film is accumulated by sputtering with the sapphire substrate situated in plasma.
(24) The production method for a Group III nitride semiconductor multilayer structure according to any one of (17) to (23) above, wherein the AlN crystal film is formed under conditions in which no oxygen-attributed peak is seen in gas analysis during plasma discharge, to obtain an AlN crystal film with an oxygen content of no greater than 5 atomic percent.
(25) The production method for a Group III nitride semiconductor multilayer structure according to any one of (17) to (24) above, wherein an AlN single-crystal film is accumulated on the sapphire substrate surface after the sapphire substrate surface has been treated with N₂ plasma or O₂ plasma.
(26) The production method for a Group III nitride semiconductor multilayer structure according to any one of (17) to (25) above, wherein the substrate temperature during accumulation of the AlN crystal film on the sapphire substrate surface is 300-800° C.
(27) The production method for a Group III nitride semiconductor multilayer structure according to any one of (17) to (26) above, wherein the film thickness of the AlN crystal film is 10-50 nm.
(28) The production method for a Group III nitride semiconductor multilayer structure according to (27) above, wherein the film thickness of the AlN crystal film is 25-35 nm.
(29) The production method for a Group III nitride semiconductor multilayer structure according to any one of (17) to (28) above, wherein the diameter of the sapphire substrate is 100 mm or greater.
(30) A lamp comprising a light emitting device according to (15) or (16) above.
(31) An electronic device incorporating a lamp according to (30) above.
(32) A machine incorporating an electronic device according to (31) above.

According to the invention it is possible to obtain a flat AlN crystal film seed layer having a high degree of crystallinity, and in particular it is possible to obtain highly reliable, high-luminance LEDs and the like by using a flat AlN crystal film seed layer that is homogeneous throughout even with large substrates having diameters of 100 mm and greater.

### BRIEF DESCRIPTION OF THE DRAWINGS

FIG. 1 is a cross-sectional schematic diagram showing an example of a Group III nitride semiconductor multilayer structure according to the invention.

FIG. 2 is a cross-sectional schematic diagram showing an example of a light emitting diode employing a Group III nitride semiconductor multilayer structure according to the invention.

FIG. 3 is a longitudinal cross-section TEM photograph of the AlN seed layer obtained in Example 1 according to the invention.

FIG. 4 is a planar surface TEM photograph of the AlN seed layer obtained in Example 1 according to the invention.

FIG. 5 is a longitudinal cross-section TEM photograph of the AlN seed layer obtained in Comparative Example 1 according to the invention.

FIG. 6 is a planar surface TEM photograph of the AlN seed layer obtained in Comparative Example 1 according to the invention.

### DESCRIPTION OF THE PRESENT INVENTION

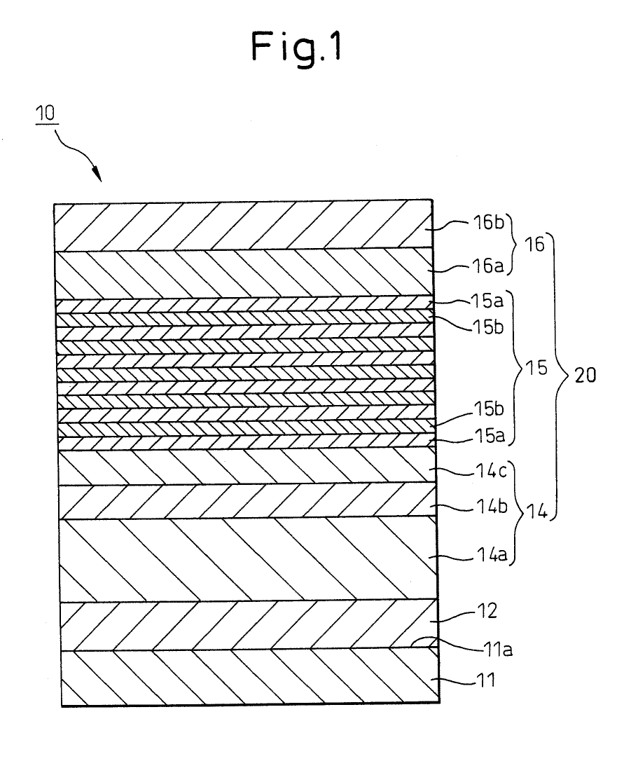

Preferred embodiments of the invention will now be explained with reference to FIGS. 1 to 6 as appropriate. The Group III nitride semiconductor multilayer structure (10) of the invention is characterized in that it is obtained by layering an n-type semiconductor layer (14), made of a Group III nitride semiconductor, a luminescent layer (15) and a p-type semiconductor layer (16), on a sapphire substrate (11), and in that it has an AlN crystal film as a seed layer (12) on the surface (11a) of the sapphire substrate (11), the AlN crystal film having no observable grain boundary in an observation field of at least 200 nm in the direction parallel to the substrate, in a longitudinal cross-section TEM (Transmission Electron Microscope) photograph, i.e. its grain boundary spacing being at least 200 nm. The longitudinal cross-section TEM is a TEM image taken on a plane perpendicular to the substrate surface, and the planar surface TEM is a TEM image taken on a plane parallel to the substrate surface.

Preferred Group III nitride semiconductors are GaN-based semiconductors such as GaN, AlN, InGaN and AlGaN (hereinafter also referred to simply as “GaN” or “GaN-based semiconductors”).

In the Group III nitride semiconductor multilayer structure of the invention, the AlN crystal film preferably has no observable grain boundary in at least a 200 nm square observation field of the planar surface TEM photograph, i.e. the grain boundary spacing is at least 200 nm, and more preferably it has no observable grain boundary in at least a 500 nm square observation field.

The longitudinal cross-section TEM or planar surface TEM photograph is obtained by preparing a sample by focused ion beam (FIB) working, performing ion thinning, and then observing with a high-resolution transmission electron microscope UHR-TEM (H-9000UHR) (product of Hitachi, Ltd.) at an acceleration voltage of 200 kV.

X-ray analysis allows quantitation of the average defect density across the entire wide range of the thin-film. However, transmission electron microscopy is used as a method of directly observing crystal defects. A method of observation from the vertical direction to the substrate surface (planar surface TEM) and a method of observation in the direction parallel thereto ((longitudinal) cross-section TEM) are also available. In cross-section TEM, if the electron beam incident direction is the <11-20> direction at high-resolution, it is possible to view the lattice image on the (0001) plane. One point in the lattice image corresponds to an atom row, and a point defect with a single atom flaw cannot be seen in TEM. Locations with shifted lattice images have single plane flaws, and this corresponds to a transposition. If a clear grain boundary exists and the plane direction is oriented in a completely different direction, the lattice image should cut off at that point. In 1991, Hiramatsu et al. conducted a detailed examination by cross-section TEM of sapphire/AlN/GaN formed with an AlN low-temperature buffer, and reported that the AlN layer consists of aggregates of columnar crystals (J. Crystal Growth 115 (1991) 628-633). The boundary face between the columnar crystals is not a distinct grain boundary as both lattice images can be seen, but closer inspection reveals a shift, some sections of which are along the C axial direction, and density variation of the image can be seen in the bright field on both sides thereof. The lack of an observable grain boundary according to the invention is the same lack of observable columnar crystals as defined by Hiramatsu et al. A magnification of about 2,000,000× is necessary to clearly identify the presence or absence of columnar crystals, and a single visual field is limited to a range of about 50 nm. To view a visual field of 200 nm, therefore, it is necessary to make 4 observations at shifted locations. The present invention is a method wherein, for heteroepitaxial growth, a crystal having intermediate physical properties between the substrate and the crystal to be grown is inserted, and since the presence of a grain boundary in that layer will result in inheritance of defects, it is essential to absolutely minimize the grain boundaries. According to the buffer layer approach of the prior art, columnar crystals are maximized and mismatches between the substrate and the crystals to be grown are absorbed, resulting in lateral growth only of those crystals having a matching plane direction, so that the desired crystal is grown; hence, the properties required for the AlN layer are completely different from the AlN seed layer of the invention. While an absolutely absence of columnar crystals is ideal, the luminescent properties for an LED can be vastly improved so long as no columnar crystals are observed at least in a 200 nm visual field.

It is relatively easy to identify columnar crystals in planar surface TEM. Variations in the bright field image appear at the locations where the plane directions are perfectly aligned and the locations where they are not aligned, when an electron beam impinges perpendicular to the (0001) plane of the columnar crystals. With accurate alignment to one columnar crystal, the grain interior is dark while the boundary is slightly shifted in orientation, thus appearing lighter. Lack of an observable grain boundary according to the invention refers to a situation in which no columnar crystals are observed at least in a 200 nm square visual field, and preferably no columnar crystals are observed at in a 500 nm square visual field.

The AlN crystal film of the invention has high crystallinity as well as a high degree of flatness as mentioned above, and preferably the arithmetic mean surface roughness (Ra) (JIS B0601) of the AlN crystal film surface is no greater than 2 angstrom and even more preferably no greater than 1.5 angstrom. The surface roughness can be measured using an atomic force microscope (AFM) or it can be optically measured using an optical surface analysis apparatus (OSA) or the like. The value obtained by AFM measurement will differ depending on the visual field of measurement. The measured values provided here are based on a 5 μm² visual field with AFM.

According to metal-organic chemical vapor deposition (MOCVD), lateral growth can be effectively utilized to reduce defects such as threading dislocation in the C axial direction, but when the thin-film is formed by sputtering, accumulation occurs basically in the growth direction. Consequently, the surface properties of the substrate are reflected in the film properties in a much more sensitive manner than with a low-temperature buffer layer. Non-uniformity of growth due to defects or contaminants present in the sapphire substrate produces grain boundaries, and therefore it is preferred to carefully manage the cleanliness of the substrate surface in order to form a grain boundary-free thin-film.

This can be achieved by beating out contaminants on the surface by plasma treatment, but the surface can become roughened by excessively strong treatment. On the other hand, if the treatment is too weak when a relatively large number of contaminants are adhering to the surface, it will not be possible to sufficiently remove them from the surface. It is preferred to maintain a consistent balance in this regard in order to produce a grain boundary-free AlN thin-film. Although the plasma treatment conditions can be varied according to the contaminant level, this is actually impossible in practice because it is extremely difficult to quantitatively evaluate the contaminant level. Specifically, it is necessary to adequately control the condition prior to loading in the sputtering apparatus. It is impossible to avoid a certain standing time from wet cleaning and drying, for polish finishing, until loading in the sputtering apparatus. Since the surface will become contaminated to some extent during this period, it is preferred to remove the contaminants if necessary before loading in the sputtering apparatus. With a long standing time, the oxygen concentration of the obtained AlN crystal film can potentially be increased in some regions, thus potentially impairing the crystallinity in those regions. Plasma treatment may not be necessary with a shorter standing time.

In the prior art described above, a low-temperature buffer method is used to grow a GaN-based crystal on a sapphire substrate. This produces characteristic behavior in which the surface becomes temporarily irregular during growth of the GaN-based semiconductor on the low-temperature buffer layer, but then gradually becomes filled during lateral growth. In situ measurement of the reflectance of the surface shows an increase at the irregular sections. A flat surface reappears and the reflectance is restored when the irregularities have been completely filled (Japanese Journal of Applied Physics, Vol. 30, No. 8, August, 1991, pp. 1620-1627).

In the process of the invention, on the other hand, the GaN crystal exhibits epitaxial growth on a grain boundary-free AlN film, and therefore the surface can grow while maintaining the flatness of the sapphire substrate. As a result, no change in the reflectance of the surface is found with in situ measurement. This also confirms that the AlN crystal film seed layer (also referred to as “seed layer” or “AlN seed layer”) of the invention has a completely different growth mechanism than a low-temperature buffer layer.

The AlN crystal film of the invention preferably has an oxygen content of no greater than 5 atomic percent and more preferably no greater than 3 atomic percent, while it is yet more preferably no greater than 0.1 atomic percent from the viewpoint of effect and cost of the seed layer.

It is the experience of the present inventors that including oxygen in the AlN thin-film creates origins for generation of grain boundaries. In order to minimize grain boundary formation, therefore, the oxygen content of the thin-film must be as low as possible. Also, the presence of grain boundaries results in a difference in growth rates between the grain boundaries and the other locations, which leads to a gradually roughened surface. It thus becomes impossible to grow a film while maintaining the flatness of the sapphire surface, and the condition gradually worsens.

Oxygen enters the film-forming apparatus by the following two possible pathways.

(1) Low degree of vacuum of base pressure. When the base pressure is at a higher degree of vacuum than 10⁻⁴ Pa the remaining gas consists almost entirely of H₂O and H₂. H₂O decomposes in plasma, thus supplying O.
(2) H₂O adheres to the shield surface even with a sufficiently low base pressure, and when plasma is generated and the shield is exposed to the plasma, the H₂O is released from the surface into the plasma. This occurs in the case of insufficient degassing treatment of the shield that is exposed to the plasma.

In order to prevent inclusion of oxygen, it is preferred first to minimize the base pressure. If an O-ring is not used in the structure, however, the apparatus becomes extremely expensive. With use of an O-ring, the chamber walls can only be heated to 100° C. due to heat resistance. Unless the walls are above 200° C., degassing from the chamber inner walls cannot be completely achieved and a limit of approximately 5×10⁻⁶ Pa is encountered. With sputtering, however, degassing occurs due to (2) above and no effect is obtained even if the base pressure is lowered. Degassing due to (2) above can be confirmed with a quadrupole mass spectrometer (for example, Transpector XPR3 by Inficon). The detection sensitivity is 10 ppm. According to the invention it was found that when oxygen is detected upon discharge, the oxygen content of the formed AlN seed layer is above 5 atomic percent.

The oxygen in the AlN thin-film can be measured by X-ray photoelectron spectroscopy (X-ray Photoelectron Spectroscopy: XPS or Electron Spectroscopy for Chemical Analysis: ESCA, such as “AXIS-NOVA” by Kratos).

The resolution in the depthwise direction in XPS is about 100 angstrom, since it is determined by the potential fly-off depth of photoelectrons. The method for compositional analysis in the depthwise direction may be Auger Electron Spectroscopy (AES) or Secondary Ionization Mass Spectroscopy (SIMS). Since an electron beam is irradiated in Auger electron spectroscopy, charge-up occurs in the case of an insulator such as AlN on the sapphire, thus preventing its use. SIMS has a sensitivity allowing quantitation of very minute trace impurities, but if these approach 1% the interior of the chamber can become contaminated, thus preventing its use. Contamination can be quantitated by SIMS analysis for those cases below the detection limit of XPS (approximately 0.5 atomic percent).

During film formation, it is common to place a shield to prevent film formation on the chamber wall surfaces. The shield is often blasted to roughen the surface, so that the accumulated film is not immediately shed. Irregularities may also be formed to prevent shedding by thermal spraying with Al instead of blasting. The shield has an increased surface area due to the blasting, such that the amount of adsorption gas is increased. In order to minimize inclusion of oxygen, therefore, the following points must be considered for the shield. (1) Shield placement: The amount of oxygen generation during discharge differs depending on the placement of the shield. For example, if it is too close to the chamber wall surface the temperature will fail to rise and adequate degassing will not be possible, thus resulting in continuous outgassing. If it is too close to the cathode it will be impacted very hard with the plasma, causing the contaminants attached during blasting to be beaten out. It is therefore preferably placed between the chamber wall surface and the heater. (2) Shield material: The heater used to heat the substrate also heats the shield, but a very high temperature can cause warping of the shield, and even its dissolution depending on the material. The shield material is optimally pure Al form the viewpoint of impurities from the shield. (3) Shield shape: The shield is preferably situated in a cylindrical manner so that the shield is evenly heated at 200° C. or higher. Thus, the placement, material and shape of the shield may be modified to reduce the oxygen generated during discharge, and as a result the oxygen content of the AlN seed layer can be reduced to below 5 atomic percent. By forming the film while performing gas analysis during discharge and confirming the absence of an oxygen-attributed peak, the oxygen content of the AlN seed layer can be controlled to below 5 atomic percent.

The Group III nitride semiconductor multilayer structure of the invention has a high degree of crystallinity, and preferably the rocking curve half-widths in X-ray diffraction for the (0002) plane and (10-10) plane of the AlN crystal film are no greater than 100 arcsec and no greater than 1.7 degrees, respectively.

The crystallinity will now be explained. Defects can be generally classified as one-dimensional, two-dimensional and three-dimensional defects, with pores being typical one-dimensional defects, dislocations being typical two-dimensional defects and grain boundaries being typical three-dimensional defects. In order to effectively use energy gaps for light emission, a single crystal is the first requirement. Single crystals have no grain boundaries, but the method of confirming this depends on the crystallinity. First, in 20 analysis by X-ray diffraction (XRD), if it is confirmed that either the diffraction peak is produced from only one surface, or spots by reflection or transmission in electron diffraction have a single type of diffraction pattern, then no definite grain boundaries exist. Next, even if the diffraction peak has exited from one plane, if the range is wide then various defects are included and the plane spacing is not constant. The sharpness of the diffraction peak is therefore the next problem. If the width is approximately the same as the incident X-ray width, then the crystallinity cannot be compared based on the width of the diffraction peak. If this is the case, then the physical quantities related to the defect density are measured to evaluate the crystallinity. For a GaN single crystal, the electron density without doping has been measured as corresponding to the N lattice defect density of the GaN. However, a value of less than 10⁺¹⁶/cm² did not serve as a useful index. A method of magnifying the defects by dry etching with Cl₂ gas and observation with an optical microscope has therefore been used (Appl. Phys. Lett. Vol. 72 (1998) 211). Also, using a scanning electron microscope (SEM) allows direct observation of the defect sites by cathode luminescence (CL), and measurement of defect density by CL has become commonplace (Jpn. J. Appl. Phys. Vol. 37 (1998) L398). An easier method for measuring defect density has been proposed, which allows the defect density to be predicted by observing the half-width of the rocking curve in XRD (J. Appl. Phys. Vol. 63 (1988) 1486). This method is simple and non-destructive while allowing total measurement, and it is therefore optimal as a method for quantitation of crystallinity. Thus, the method is adopted according to the invention to quantitate and express the crystallinity. The p-GaN layer, as the final layer of the LED structure, is analyzed by X-ray diffraction and the half-width of the rocking curve in X-ray diffraction for the (0002) plane and (10-10) plane of the p-GaN crystal (FWHM) is used.

When using a conventional AlN or GaN buffer layer, the crystallinity of the buffer layer itself is such that the FWHM on the (0002) plane is on the order of several thousand to several tens of thousands of arcsec, while the (10-10) plane is greater than 3 degrees, and therefore measurement is impossible under the same set conditions. Even if the crystallinity improves with the subsequent lamination, the assumed limits for the p-GaN layer are 100 arcsec on the (0002) plane and 300 arcsec on the (10-10) plane. The crystallinity of 300 arcsec on the (10-10) plane corresponds to a dislocation density of 1×10⁹/cm³ as measured by the CL method.

According to the invention, measurement of the half-width of the rocking curve is accomplished using CuK α-rays as the X-ray source, an incident beam with an angle of divergence of 0.01 degree, and a “PANalytical X'pert ProMRD” apparatus by Spectris Co., Ltd.

Also, measurement of the rocking curve on the (0002) plane is accomplished by finding the peak corresponding to the (0002) plane, then optimizing 2θ and ω, and measuring the rocking curve in the direction in which the peak intensity is greatest. By measuring the rocking curve in this manner, it is possible to compare the rocking curve half-widths of different samples to be measured since it will compensate for errors caused by the method of mounting the substrate in the apparatus and the orientation direction with respect to the substrate, which will differ depending on the sample to be measured.

Measurement of the rocking curve on the (10-10) plane can be accomplished based on the X-rays that penetrate into the plane under conditions with total reflection of X-rays. Specifically, when an X-ray source that diverges in the perpendicular direction with respect to the sample to be measured that is situated horizontally is incident to the horizontal direction, a portion undergoes total reflection, and these X-rays are utilized. The detector was fixed at the 2θ position corresponding to the (10-10) plane, and φ scan was conducted. In addition, the peak of hexagonal symmetry is measured and the optical system is fixed at the peak position of maximum intensity, after which 2θ and ω are optimized and rocking curve measurement performed.

When it is difficult to create incidence of the X-rays under total reflection conditions, the (10-10) diffraction data may be estimated from the (10-12) diffraction results.

For most Group III nitride compound semiconductors, the XRC spectrum half-width on the (0002) plane is an index of the crystal tilt (slight slope of the grown crystal plane orientation with respect to the growth direction), while the XRC spectrum half-width on the (10-10) plane is an index of the twist (slight slope of the crystal direction within the growth plane) (Jpn. J. Appl. Phys. Vol. 38 (1999) L611).

### (Sapphire Substrate)

According to the invention, the sapphire substrate (11) surface (11a) is preferably first cleaned to a satisfactory degree. The cleaning preferably removes as much as possible the particles such as residual polishing agent or sapphire dust; surface damage created during handling, or extremely gentle irregularities and minute compositional variations, known as “subsurface damage”; organic material thin-film resulting from attachment of organic material floating in the air onto the surface; and particles generated by contact with the jig during processing or dirt present in the environment.

The flatness of the substrate surface preferably satisfies the following conditions. The single crystal orientation is preferably on the C-plane (0001).

A: Ra is no greater than 3 angstrom, preferably no greater than 2 angstrom, and even more preferably no greater than 1 angstrom.

B: It has a suitable off-angle of preferably 0.1-0.7 degrees, and even more preferably 0.3-0.6 degrees.

C: The step of each plane is clearly evident to a level allowing observation with an atomic force microscope (AFM) or the like. The surface density is preferably as high as possible.

D: Protrusions other than the steps produced by the off-angle are preferably as few as possible.

Although a lower number of defects is of course preferred for the crystallinity of a sapphire single crystal, it is important to guarantee the aforementioned surface properties since heteroepitaxial growth is performed on the substrate, and slight differences in the crystallinity of the substrate will not significantly affect the characteristics of the GaN-based semiconductor after epitaxial growth. Thus, the method of growing the sapphire single crystal should be selected with a priority view to cost.

The present invention exhibits a particularly notable effect when the diameter of the sapphire substrate is 100 mm or greater.

The sapphire substrate is placed in a film-forming apparatus that generates plasma in a vacuum, and an AlN crystal seed layer is formed. Even if the sapphire substrate surface has been sufficiently cleaned as explained above, a certain period of time will be required from the completion of cleaning and drying of the substrate until its loading in the film-forming apparatus. Even if it is vacuum packed in a cleanroom and removed in a cleanroom, the surface will usually vary within a wide range depending on the conditions. Thus, plasma is preferably used immediately before placement in the vacuum apparatus for film formation to order the sapphire surface.

The important parameters as conditions for the surface plasma treatment are the voltage application method, the type of gas, the gas pressure, the applied power and the temperature.

### (Voltage Application Method)

Methods for producing plasma in the chamber are largely classified into 4 types, depending on whether the applied voltage is DC or RF, and when the chamber is used as the earth, whether the object of voltage application is the target or the substrate. It is preferred to apply an RF voltage to the substrate for ordering immediately before film formation on the surface of the sapphire substrate, for 2 reasons, namely because the sapphire substrate is an insulator and because the atoms flying off from the target can attach to the substrate surface, thus interfering with the purpose.

### (Type of Gas)

The type of gas used to generate the plasma is not particularly restricted. However, since the main purpose is to produce fly-off of organic material, and atoms of the sapphire substrate surface that are beaten off may result in deterioration of the surface steps, the use of a highly reactive gas is preferably avoided. Even with an inert gas, however, heavy atoms are not preferred since the destructive effect will be prominent. He and H₂ may be used, but their plasma discharges are unstable and if Ar is combined for stability the destructive force of Ar will become a problem. O₂ or N₂ is therefore preferred. However, O₂ gas remaining in the chamber even in trace amounts can potentially inhibit crystal growth during the subsequent sputtering of AlN, and therefore treatment using N₂ plasma is most preferred. Naturally, a rare gas such as Ar may be combined to maintain plasma stability.

### (Applied Power and Gas Pressure)

The power introduced is preferably as low as possible, at the minimum level which keeps the plasma stable. The introduced power is optimally in the range of about 10-100 W, given the chamber and cathode sizes used for the invention. A high gas pressure will cause the particles to impact each other, thus losing kinetic energy. Also, a low gas pressure will cause the particles with high kinetic energy to strike the substrate surface, and therefore a high pressure within a range for plasma stability is preferred. However, overly increasing the gas pressure will require high power to maintain plasma stability. A power of greater than 100 W may introduce more defects on the surface than can be ordered. The most optimal range, therefore, is 0.8-1.5 Pa.

### (Temperature)

The temperature is not a very important parameter for ordering the surface of the sapphire substrate. The purpose can be achieved with any temperature from room temperature to 1000° C., although 300-950° C. is preferred. However, it is preferably the same temperature as in the subsequent film formation, since it is immediately before film formation. Damage may be excessive if the temperature is higher than 800° C. The surface plasma treatment may also be carried out in a separate chamber, which is advantageous in that throughput can be increased and a different temperature can be set, but this will require more time from the surface plasma treatment until the subsequent film formation, and may result in contamination of the surface.

The AlN seed layer (12) is then formed. A single crystal is a crystal with no grain boundaries and with the same crystal orientation in all sections. If it is not a perfect crystal, however, it will have some defects and the crystal orientation will vary minutely in the crystal, depending on the location of the defects. Polycrystals will therefore be present to the extent of defects, and it is difficult in practice to distinguish where the single crystal begins. It is thus necessary to satisfy the following conditions so that grain boundaries cannot be seen in at least a 200 nm visual field of the TEM cross-section observation of the AlN seed layer on the sapphire substrate.

For a C-plane thin-film, the width of the diffraction peak at the (0002) plane is a problem for crystallinity. A sufficiently sharp diffraction peak means a defect-free surface with a constant plane spacing. The measure of orientation of all sections in the same direction is indicative of the rocking curve sharpness (FWHM). If this is poor then growth may occur in any direction, making it impossible to ensure a smooth surface. It is therefore necessary to consider both the (0002) plane and the (10-10) plane, for crystallinity as a seed layer. The FWHM on the (0002) plane is an index of the distribution of angles with respect to the substrate surface, and it must therefore be extremely sharp as a prerequisite condition. Next, the half-width of the rocking curve at the (10-10) plane is an index of how many locations are partially rotated as viewed from the direction perpendicular to the substrate surface. If this is large, defects will penetrate in the C axial direction, and therefore it is an important parameter for minimizing the leak current. However, it may be sufficient for the seed layer if no discontinuous boundaries are present. It can be confirmed that a sample wherein the AlN seed layer of the invention has a rocking curve half-width at the (10-10) plane of no greater than 1.7, has no discontinuous grain boundaries in a 200 nm×200 nm observation field in planar surface TEM. If the rocking curve half-widths (FWHM) in X-ray diffraction for the (0002) plane and (10-10) plane of the AlN are no greater than 100 arcsec and 1.7 degrees, respectively, it will be possible to accomplish epitaxial growth of GaN-based semiconductor thereon, and the crystallinity of the p-GaN contact layer as the final layer grown on the LED structure can be achieved to a level such that the XRC FWHM are, preferably, 60 arcsec and 250 arcsec at the (0002) plane and (10-10) plane, respectively.

In order to obtain the Group III nitride semiconductor multilayer structure described above by the production method for a Group III nitride semiconductor multilayer structure of the invention, the oxygen content in the obtained AlN crystal film is preferably controlled to be no greater than 5 atomic percent. The control method may be a method as described above.

Other important parameters for production of the AlN seed layer of the invention are the type of target, the methods for voltage and magnetic field application, the type of gas, the distance between the target and substrate, the plasma form and the volume of trapped plasma, the gas pressure, the applied power and the film-forming temperature. Each of these will now be explained in order.

### (Type of Target and Methods for Voltage and Magnetic Field Application)

Methods for producing plasma in the chamber are largely classified into 4 types, depending on whether the applied voltage is DC or RF, or when the chamber is used as the earth, whether the object of voltage application is the target or the substrate. The target for formation of AlN may be a high purity AlN target, or high purity Al may be used as the target and N₂ introduced into the gas for decomposition of N₂ by the plasma and reaction between Al and N. If it is attempted to sinter high purity AlN powder it will be necessary to add a sintering aid such as CeO₂, and it will then be difficult to obtain a high purity, dense AlN target. High purity Al, on the other hand, is commercially available up to 6N. A purity of at least 5N is preferred for the purpose of the invention. When discharge is produced by DC, the target must be an electric conductor. Thus, selecting high purity AlN as the target will necessarily require RF voltage application. If the target is high purity Al, either DC or RF may be used. However, AlN can potentially be formed on the Al surface creating insulation, which can cause electrical charge accumulation and a lightning strike phenomenon. With DC, therefore, pulse application may be used to avoid formation of an AlN film. The advantages and disadvantages of DC and RF are as follows.

Advantages of DC: Inexpensive power source. Easy to control. Distinct cathode and anode allow plasma beating locations and film-forming locations to be defined. Design can be easily modified to reduce impurities.

Disadvantages of DC: Narrow range of stable discharge. Narrow kinetic energy range.

Advantages of RF: Wide range of stable discharge. Wide kinetic energy range.

Disadvantages of RF: Expensive power source. Requires a matching box, and time until discharge formation is prolonged. Lack of distinct cathode and anode results in beating of particles by plasma from all sections of the shield. Difficult to modify design for reduced impurities.

With both DC and RF, it is necessary to create a magnetic field to stabilize the plasma. The magnetic field application may be from a permanent magnet or electromagnet, and usually a magnet is moved for a more uniform magnetic field. When the target is circular it is common to rotate a permanent magnet, and when the target is square it is common to use reciprocating motion of a permanent magnet. When a permanent magnet cannot be suitably placed, an ICP electrode type system with a coil on the outside may be used. Since the plasma density depends primarily on the strength of the magnetic field, a uniform magnetic field strength is necessary to obtain a uniform film thickness. Different magnetic field generating methods are often used in combination.

To summarize the above, RF discharge using a high purity Al target is most suitable for formation of the AlN seed layer.

### (Type of Gas)

The type of gas used to generate the plasma may be a rare gas alone with an effective mass such as Ar, Xe or Kr (preferably Ar) if the target is AlN (Ar will be referred to below as the rare gas), but if the target is Al it is necessary to use Ar and N₂. Using N₂ alone will produce AlN before the Al atoms are beaten out, and the film-forming speed will therefore be minimal. Ar alone will result in formation of a metal Al thin-film. AlN will be formed if the amount of N₂ is increased, but a low N₂ gas partial pressure will result in insufficient N₂ for the AlN, causing coloration of the film. For exact nitriding of the fly-off atoms from Al, it is necessary for the activated N₂ to be equal in number to the Al atoms that are beaten off. If it is in excess, a large number of defects will be introduced into the AlN crystal film, resulting in coloration. It is therefore preferred to use a mixed gas with a suitable proportion of Ar and N₂. The suitable proportion will vary depending on the gas pressure and applied power. The speed at which Al is beaten off depends on the applied power but not on the gas pressure. However, the activation rate of N₂ is higher with a lower gas pressure. Thus, it is preferred to lower the proportion of Ar with a low gas pressure, while it is also preferred to lower the proportion of Ar when the applied power is high. The nitrogen starting material used for the invention may be a commonly known compound such as NH₃. If nitrogen gas is used as the nitrogen starting material a more convenient apparatus can be used, but as N₂ is highly stable and difficult to activate it will be difficult to obtain a high reaction rate. According to the invention, the sapphire substrate is placed in the plasma and activation of N₂ near the substrate surface is utilized, thus allowing a practical film-forming speed to be achieved with N₂, though lower than ammonia.

### (Distance Between Target and Sapphire Substrate)

If the sapphire substrate has a diameter of 100 mm, the target size will need to have a diameter of about 200 mm to form a uniform film over the entire surface. It is common to apply a magnetic field to stabilize the plasma, in which case the magnet is placed behind the target. Since the magnetic field is concentrated on the target surface, the plasma density increases on the target surface. According to the invention, the purpose is to react the plasma particles with high energy on the substrate surface, and therefore the substrate is preferably situated at the location of highest plasma density. If the distance between the target and substrate is too great, it will not be possible to place the substrate at the location of high plasma density. For a target with a diameter of 200 mm, for example, the distance between the target and sapphire substrate is preferably about 40-80 mm. The distance, according to the invention, is preferably such that the sapphire substrate is situated in the plasma, in order to accumulate an AlN crystal film by sputtering.

### (Plasma Form and Volume of Trapped Plasma)

If the plasma reaches the wall surface of the chamber, the wall surface becomes contaminated and removal becomes difficult, and it is therefore commonplace to use a shield to trap the plasma. The shield not only prevents contamination of the chamber wall surfaces, but if the chamber is earthed it functions as an electrode, thus defining the form of the plasma. The exhaust efficiency must be improved to increase the degree of vacuum, and therefore a smaller chamber size is preferred. However, trapping the plasma in a very small volume will result in beating of the shield by the plasma, causing the shield components to enter the forming film. Water molecules will also unavoidably adhere to the shield surface, and when they are beaten and released by the plasma this results in inclusion of OH or O into the film. It is preferred, then, to place the shield at a certain distance instead of adjacent to the target, and preferably with a diameter of about at least 300 mm.

### (Gas Pressure and Applied Power)

The base pressure is the basic parameter determining the film quality. According to the invention, a suitable high vacuum is no greater than 1×10⁻⁵ Pa and preferably 5×10⁻⁶ Pa. At a lower degree of vacuum the impurities such as oxygen in the atmosphere may enter the formed AlN film, thus potentially introducing defects into the crystal. In addition, even with sufficient lowering of the base pressure, impurities such as water on the shield surface will be beaten out when the plasma is generated, thus lowering the film quality.

With a high gas pressure, the particles will impact each other in the plasma, thus resulting in kinetic energy loss. Because reaction of high kinetic energy Al and N on the substrate surface is necessary in order to form an AlN seed layer according to the invention, a very high gas pressure is not preferred. On the other hand, a very low gas pressure is also not preferred because it will cause a greater number of N₂ plasma particles to impact and react with the Al target. An ordinary sputtering gas pressure of 0.3-0.8 Pa is therefore suitable. The applied power results in a proportional film-forming speed, and hence sufficient speed will not be obtained if it is too low. Unavoidable contamination by residual gas components such as O₂ and H₂O in the atmosphere occurs, but the amount of inclusion thereof is thought to be consistent with respect to time. A slow film-forming speed will therefore increase the amount of inclusion, thus undesirably lowering the purity of the film. Since a maximally high film-forming speed is necessary the applied power should also be high. However, very large power application will result in direct exposure of the shield to the plasma, thus generating impurities from the shield. A suitable applied power is therefore 500-2500 W for a target with a diameter of about 200 mm. Also, the suitable gas pressure will vary depending on the applied power. A relatively high gas pressure within the suitable range is preferred when the applied power is high, while a relatively low gas pressure within the suitable range is preferred when the applied power is low.

### (Film-Forming Temperature)

The substrate temperature during film formation is preferably 300-800° C. At a temperature of below 300° C., the distance will no longer be sufficient for the atoms to reach the substrate and move to create the single crystal, such that the total surface will not be covered and pits will begin to be formed. In order to form a seed layer according to the invention on the substrate surface it is advantageous to raise the temperature enough to initiate decomposition of AlN, and since that temperature is about 1200° C. the upper limit is even higher; however, because the fixed jig and shield around the substrate will also rise in temperature commensurately, resulting in more degassing and increased inclusion of impurities, the results will not necessarily be satisfactory when a very high temperature is set. The temperature should therefore not be increased above 800° C. in the actual process. Nevertheless, if a structure that permits a high degree of vacuum to be maintained can be achieved at even higher temperature, it may be even more advantageous for increased crystallinity to form the film at higher temperature.

The film thickness of the AlN crystal film is 10-50 nm and preferably 25-35 nm. With a thickness of less than 10 nm, it will be difficult to adequately increase the (0001) plane crystallinity of the GaN crystal accumulated thereover. With a thickness of greater than 50 nm, on the other hand, the accumulated GaN will tend to have poorer crystallinity on the (10-10) plane.

According to the invention, a Group III nitride semiconductor multilayer structure (10) is obtained by layering a Group III nitride semiconductor layer (20) composed of an n-type semiconductor layer (14), a luminescent layer (15) and a p-type semiconductor layer (16) Group III nitride semiconductor layer, on the seed layer (12) of an AlN crystal film. Growth of a GaN-based single crystal on a seed layer (12) formed on a sapphire substrate (11) is relatively easy because it is similar to homoepitaxial growth. Growth of GaN-based single crystal structures with low defect density are realized by the widely employed method of MOCVD. The MOCVD method may be according to the commonly used protocol. This will now be summarized.

Hydrogen (H₂) or nitrogen (N₂) are employed as the carrier gas, trimethylgallium (TMG) or triethylgallium (TEG) as the source of Ga as the Group III material, trimethylaluminum (TMA) or triethylaluminum (TEA) as the Al source, trimethylindium (TMI) or triethylindium (TEI) as the In source and ammonia as the source of N as the Group V material.

Also, monosilane (SiH₄) or disilane (Si₂H₆) may be utilized as the Si source for dopant element n-type impurities. For dopant element p-type impurities, biscyclopentadienylmagnesium (Cp₂Mg) or bisethylcyclopentadienylmagnesium (EtCp₂Mg) may be used as the Mg source.

The carrier gas flowing through during this time may be a common gas, such as hydrogen or nitrogen which are widely used in gas phase chemical film-forming processes such as MOCVD. The substrate temperature must be lower than the initial GaN decomposition temperature. GaN begins to undergo trace decomposition at above 950° C., with definite decomposition at 1000° C. and higher. The decomposition temperature depends on the crystallinity of the GaN, and since decomposition presumably begins from the defect sites, a crystal with fewer defects will have a higher decomposition temperature. Thus, if growth is carried out at the temperature at which trace decomposition begins, the defect sites will undergo decomposition leaving only the non-defect sites, and therefore temperature setting is extremely important for achieving growth with minimal defects. Film formation at a suitable temperature can reduce defects by promoting growth by the mechanism explained above.

The GaN-based single crystal near the AlN crystal film seed layer/GaN-based single crystal interface will contain a relatively large number of defects. If this is grown to a constant thickness, the defects will gradually be removed, yielding a single crystal with a very low defect density. The thickness necessary to remove the defects is a minimum of 2 μm, while a thickness of 4-8 μm is the usual range for obtaining satisfactory crystallinity. Any greater thickness will merely dilute the effect and will also increase warping. In extreme cases the crystal may begin to exhibit cracks. Excessive warping can impede photolithography in the element assembly process in which the electrodes are attached.

The GaN-based single crystal film grown on the AlN crystal film seed layer of the invention has excellent crystallinity. The index for quantitation of the crystallinity will now be explained again. The half-width of the rocking curve in X-ray diffraction of the GaN crystal on the (0002) plane and (10-10) plane (FWHM: Full Width at Half-Maximum for (0002) and (10-10) diffraction) is used. The rocking curve half-width on the (0002) plane (FWHM) is no greater than 100 arcsec and preferably no greater than 60 arcsec, while the rocking curve half-width on the (10-10) plane is no greater than 300 arcsec and preferably no greater than 250 arcsec. The FWHM on the (10-10) plane is thought to correlate with the threading dislocation, and this means therefore that the threading dislocation is extremely low. The luminous efficiency correlates with the amount of threading dislocation. This is because the luminous efficiency is the amount of current flowing between p-GaN and n-GaN that is converted to light, and a current that flows through threading dislocation will correspondingly lower the luminous efficiency.

Growth of the GaN-based semiconductor layer is basically the same as growth on a low-temperature buffer using AlN or GaN. However, since the growth temperature might be selected as the approximate temperature at which decomposition begins, it can be increased with lower defect density, as explained above. As growth occurs from the AlN crystal film seed layer according to the invention, one feature of the invention allows growth from regions of relatively low defect density.

The relationship with the crystallinity of the AlN crystal film seed layer will now be explained once more. When using a conventional AlN or GaN buffer layer, the crystallinity of the buffer layer is such that in terms of the FWHM it is on the order of several thousand to several tens of thousands of arcsec on the (0002) plane, while the FWHM cannot be measured on the (10-10) plane. As regards the crystallinity of the AlN crystal film seed layer, however, the rocking curve half-widths in X-ray diffraction on the (0002) plane and (10-10) plane (FWHM) are no greater than 100 arcsec and no greater than 1.7 degrees, respectively. For the (0002) plane, it is sufficient for the GaN crystal to inherit the crystallinity. On the (10-10) plane it decreases during growth of the GaN. Although the mechanism of defect reduction during growth by MOCVD is the same, the densities of defects remaining at the starting time point are completely different, and therefore it is extremely difficult to limit the FWHM on the (10-10) plane to no greater than 300 arcsec regardless of how appropriate the conditions are for thick accumulation of the polycrystals.

According to the invention, a Group III nitride semiconductor multilayer structure (10) is obtained by subsequently layering a Group III nitride semiconductor layer (20) composed of an n-type semiconductor layer (14), a luminescent layer (15) and a p-type semiconductor layer (16) Group III nitride semiconductor layer, on the seed layer (12) of an AlN crystal film. For example, there is formed on the seed layer (12) a GaN-based semiconductor layer (20) comprising an n-type contact layer (14b), an n-type clad layer (14c), a luminescent layer (15) composed of a barrier layer (15a) and well layer (15b), a p-type clad layer (16a) and a p-type contact layer (16b). A preferred embodiment will be described below, although there is no limitation thereto and the film-forming method may also be common MOCVD.

### (N-Type Semiconductor Layer)

In the n-type semiconductor layer (14) containing the n-type contact layer (14b) and n-type clad layer (14c), a ground layer (14a) may be provided under the n-type contact layer (14b). The material used for the ground layer (14a) may be a GaN-based compound semiconductor, with AlGaN or GaN being especially preferred. The film thickness of the ground layer is preferably 0.1 μm or greater, more preferably 0.5 μm or greater, and most preferably 1 μm or greater.

The n-type contact layer (14b) is preferably doped with an n-type impurity such as Si or Ge, and the GaN-based semiconductors composing the ground layer and n-type contact layer preferably have the same composition. The total thicknesses of these films is not particularly restricted but are preferably 1-20 μm.

An n-type clad layer (14c) is provided between the n-type contact layer (14b) and luminescent layer (15). The film thickness is not particularly restricted but is preferably 5-500 nm.

### (Luminescent Layer)

There are no particular restrictions on the luminescent layer (15), likewise, but it preferably has a multiple quantum well structure with alternate lamination of the n-type GaN layer serving as the barrier layer (15a) and the GaN layer serving as the well layer (15b).

TMI is preferably supplied for growth of the GaInN layer, with the TMI being intermittently supplied while controlling the growth time. The carrier gas is preferably N₂. The film thicknesses of the barrier layer (n-type GaN layer) and well layer (GaInN layer) are selected for conditions that result in the highest luminous output. The Group III starting material supply rate and growth time may be appropriately selected upon determining the optimum film thickness. The growth temperature is preferably between 700° C. and 1000° C., as the susceptor temperature. During growth of the well layer, however, In will be poorly incorporated into the grown film if the temperature is high, such that solid solution of the amount of 1n required for luminescence at the prescribed wavelength will not be possible. The growth temperature is therefore selected in a range that is not too high. A maximally high temperature for the barrier layer will help maintain the crystallinity, but if it is too high the GaInN in the well layer will decompose. The luminescent layer (15) is preferably completed upon growth of the final barrier layer (15a).

### (P-Type Semiconductor Layer)

A p-type clad layer (16a) and p-type contact layer (16b) form the p-type semiconductor layer (16). The p-type clad layer (16a) has a composition such that its band gap energy is greater than the band gap energy of the luminescent layer (15), and it is not particularly restricted so long as trapping of the carrier into the luminescent layer (15) is possible. AlGaN, for example, is suitable for use. The film thickness of the p-type clad layer (16a) is not particularly restricted but is preferably 1-400 nm.

The p-type contact layer (16b) is preferably GaN or AlGaN, and the film thickness is preferably 50-300 nm and even more preferably 100-200 nm. The p-type impurity is also not particularly restricted, and Mg may be mentioned as preferable.

Growth of the p-type contact layer (16b) is preferably accomplished in the following manner, for example. TMG, TMA and the dopant Cp₂Mg are fed onto the p-type clad layer (16a) together with a carrier gas (hydrogen or nitrogen, or a mixture thereof) and NH₃ gas. The growth temperature during this time is preferably in the range of 980-1100° C., as the susceptor temperature. It is preferably 830-970° C. as the wafer temperature. At a lower temperature, an low-crystallinity epitaxial layer will be formed and the hole density of the p-GaN may not increase. At higher temperatures, the GaInN of the well layer, in the luminescent layer situated as the lower layer, may decompose leading to deposition of 1n.

The growth pressure is not particularly restricted but is preferably no greater than 50 kPa (500 mbar). This is because concentration distribution of the Mg incorporated as dopant in the p-type contact layer will be homogeneous in the two-dimensional direction (the in-plane direction of the growth substrate) if the growth conditions are below 50 kPa (500 mbar).

The growth rate is determined by measuring the film thickness of the p-type contact layer by TEM observation or spectroscopic ellipsometry of the wafer cross-section, and dividing it by the growth time. The Mg concentration of the p-type contact layer may be determined using an ordinary mass spectrometer (SIMS).

### (Fabrication of Transparent Electrode/Cathode Bonding Pad and Anode Bonding Pad)

Photolithography is used to form a translucent cathode (17) on the p-type contact layer (16b) of the layered semiconductor layer (20) obtained in the manner described above. As explained below, a cathode bonding pad (18) is formed on the translucent cathode (17).

The sputtering for formation of the transparent electrode may be carried out under conditions appropriately selected from among publicly known conditions, using a known sputtering apparatus. The substrate laminated with the gallium nitride-based compound semiconductor layer is then housed in a chamber. The interior of the chamber is evacuated to a degree of vacuum of 10⁻⁴-10⁻⁷ Pa. Discharge is carried out after adjusting the pressure to 0.1-10 Pa by introduction of Ar gas into the chamber. The pressure is preferably set within the range of 0.2-5 Pa. The supplied electric power is preferably in the range of 0.2-2.0 kW. The discharge time and power supply can be adjusted to modify the thickness of the formed layer.

The exposure region (14d) on the n-type contact layer (14b) is then exposed by photolithography and dry etching. After forming a protective film over the entire surface, the pad forming sections are removed by photolithography and the cathode bonding pad (18) and anode bonding pad (19) are simultaneously formed on the translucent cathode (17) and the n-type contact layer (14b) by vacuum vapor deposition. Alternatively, the cathode bonding pad (18) and anode bonding pad (19) may each be formed without using the aforementioned protecting film.

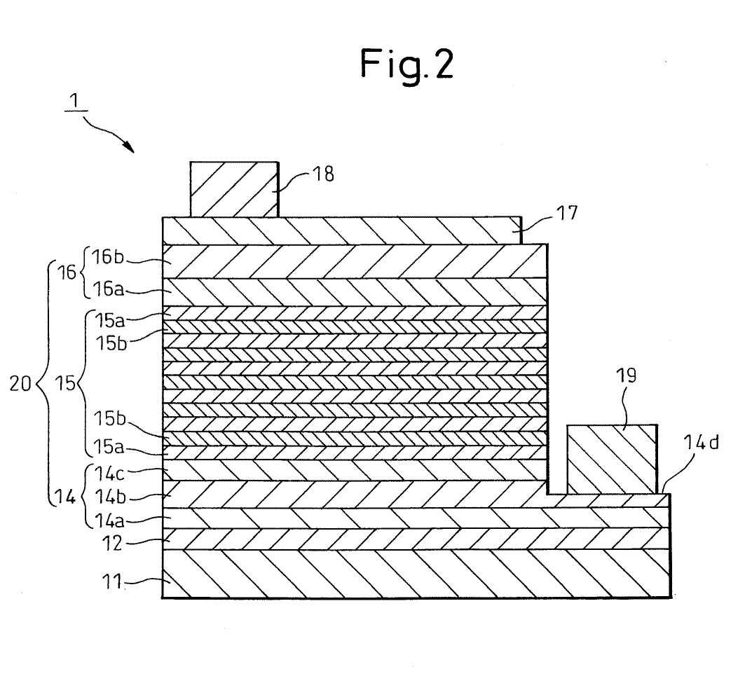

The semiconductor wafer on which the electrodes have been formed is divided into chips by an ordinary process to obtain a light emitting diode 1 as shown in FIG. 2 (without the protecting film).

The production method for the light emitting diode of the invention is not limited to the example described above, and formation of the GaN-based semiconductor layer may be carried out by combining any methods used to grow semiconductor layers, such as sputtering, MOCVD (Metal-Organic Chemical Vapor Deposition), HVPE (Halide Vapor Phase Epitaxy) or MBE (Molecular Beam Epitaxy).

The light emitting diode of the invention may be used not only for the aforementioned light emitting diodes, but also for photoelectric conversion elements such as laser elements and light receiving elements, or electronic devices such as heterojunction bipolar transistors (HBT) and high electron mobility transistors (HEMT). Such semiconductor elements with various structures are known, and the structure of the light emitting diode of the invention is not restricted in any way even for any of these known element structures.

The light emitting diode of the invention may be provided with, for example, a transparent cover by means known in the field for use as a lamp. Techniques for altering emitted light by combination of light emitting diodes and fluorescent materials are also known in the prior art, and any such techniques may be employed without any restrictions whatsoever. By appropriate selection of a fluorescent material, for example, it is possible to obtain emission with a longer wavelength than the light emitting diode, or by combining the luminous wavelength of the light emitting diode itself with the converted wavelength from the fluorescent material, it is possible to obtain a lamp that emits white light.

Usage as a lamp may be for a general purpose lamp type, a portable backlight side-view type, top-view type used in displays, or the like.

Since a lamp made from a gallium nitride-based compound semiconductor light emitting diode of the invention has high luminous output and low driving voltage, electronic devices such as cellular phones, displays, panels and the like incorporating lamps made with this technology, or machines such as automobiles, computers or game devices incorporating such electronic devices, can be driven with low electric power while exhibiting high characteristics. In particular, an effect of reduced power consumption is exhibited for battery-driven devices such as cellular phones, games, toys and automobile parts.

### EXAMPLES

### Example 1

### (1) AlN Crystal Film Seed Layer

A C-plane sapphire substrate (11) with a diameter of 100 mm and a thickness of 0.9 mm was prepared. The substrate was cut at an off-angle of 0.35 degrees, and the surface (11a) had a roughness of Ra≦2 angstrom. The substrate was cleaned immediately before loading by placement in purified water rotating at 500 rpm, and then the rotation speed was increased to 2000 rpm for drying. It was then set in a sputtering apparatus with a 5N high purity Al target to form a seed layer (12). The target diameter was 200 mm, and the distance between the target and sapphire substrate (TS distance) was 60 mm. The application method for surface plasma treatment employed RF power applied between the sapphire substrate and chamber. The application method for the AlN seed film formation employed RF power applied between the target and chamber. The film-forming conditions were as follows, with the process divided into two stages: surface plasma treatment for ordering of the surface and treatment for AlN film formation.

### (Surface Plasma Treatment)

Heater temperature: 600° C., Ar flow rate: 0 sccm, N₂ flow rate: 75 sccm, applied power: 30 W, total gas pressure: 1.0 Pa, base pressure: 4×10⁻⁶ Pa, TS distance: 60 mm, application time: 15 seconds

### (Aln Film-Formation)

Heater temperature: 600° C., Ar flow rate: 25 sccm, N₂ flow rate: 75 sccm, applied power: 1500 W, total gas pressure: 0.5 Pa, base pressure: 4×10⁻⁶ Pa, TS distance: 60 mm, application time: 100 seconds

Upon completion of the treatment, the wafer was removed from the apparatus and measured by XRD. The properties of the obtained AlN seed film were as follows.

Ra: 1.2 angstrom, oxygen concentration: 2.8 atomic percent, FWHM (0002): 31 arcsec, FWHM (10-10): 1.4 degrees

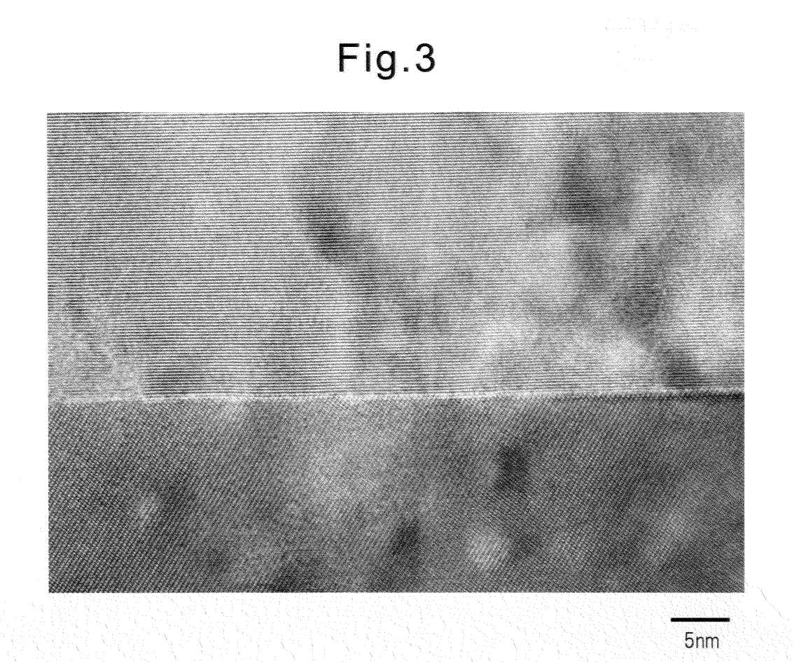

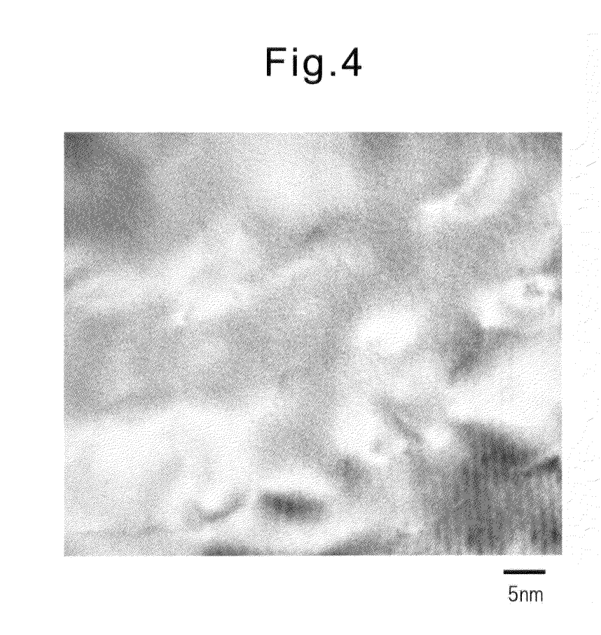

FIG. 3 and FIG. 4 show, respectively longitudinal cross-section TEM and planar surface TEM photographs of the seed layer (12) of the obtained AlN crystal film. The two layers seen in FIG. 3 are the sapphire substrate (lower layer) and AlN crystal film seed layer (upper layer). The visual field of FIG. 3 is approximately 60 nm, and even with 4 visual field observations, no density variation was seen in the lattice image and no grain boundaries were visible. In FIG. 4 the visual field is 50 nm×60 nm, and with 200 nm square observation with gradual slight shift, no grain boundaries corresponding to columnar crystals were observable.

### (2) GaN-Based Semiconductor Multilayer Structure

A GaN-based semiconductor layer (20) was grown next by MOCVD. The growth conditions were as follows.

(A: Ground Layer (14a) (Undoped GaN))

Total gas pressure: 400 mbar; susceptor temperature: 1100° C.; H₂ flow rate: 30 slm; N₂ flow rate: 0 slm; TMG flow rate: 300 sccm; NH₃ flow rate: 7 slm; SiH₄ flow rate: 0 sccm

(B: n-Contact Layer (14b)(n-GaN))

Total gas pressure: 400 mbar; susceptor temperature: 1100° C.; H₂ flow rate: 30 slm; N₂ flow rate: 0 slm; TMG flow rate: 300 sccm; NH₃ flow rate: 7 slm; SiH₄ flow rate: 120 sccm

(C: n-Clad Layer (14c))

Total gas pressure: 400 mbar; susceptor temperature: 760° C.; H₂ flow rate: 0 slm; N₂ flow rate: 50 slm; TMG flow rate: 0 sccm; TEG flow rate: 250 sccm; NH₃ flow rate: 18 slm; TMI flow rate: 20 sccm; SiH₄ flow rate: 50 sccm; Cp₂Mg flow rate: 0 sccm

### (D: Luminescent Layer (15))

Total gas pressure: 400 mbar; susceptor temperature: 760/980° C.; H₂ flow rate: 0 slm; N₂ flow rate: 50 slm; TMG flow rate: 0 sccm; TEG flow rate: 150 sccm; NH₃ flow rate: 18 slm; TMI flow rate: 120/0 sccm; SiH₄ flow rate: 0/30 sccm; Cp₂Mg flow rate: 0 sccm

(E: p-Clad Layer (16a))

Total gas pressure: 400 mbar; susceptor temperature: 1040° C.; H₂ flow rate: 30 slm; N₂ flow rate: 0 slm; TMG flow rate: 180 sccm; TEG flow rate: 0 sccm; NH₃ flow rate: 21 slm; TMA flow rate: 50 sccm; TMI flow rate: 0 sccm; SiH₄ flow rate: 0 sccm; Cp₂Mg flow rate: 130 sccm

(F: p-Contact Layer (16b))

Total gas pressure: 400 mbar; susceptor temperature: 1040° C.; H₂ flow rate: 30 slm; N₂ flow rate: 0 slm; TMG flow rate: 180 sccm; TEG flow rate: 0 sccm; NH₃ flow rate: 21 slm; TMI flow rate: 0 sccm; SiH₄ flow rate: 0 sccm; Cp₂Mg flow rate: 260 sccm

The growth speed was 2 μm/hr for each layer.

The Ga starting material was trimethylgallium (TMG) as an organometallic material, and the N source was ammonia (NH₃). The carrier gas was H₂. A dopant was further added for formation of the n-contact layer (14b)(n-GaN) layer. Si was used as the dopant material for the n-type semiconductor layer. Monosilane (SiH₄) was used as the Si starting material. The dopant was supplied together with the carrier gas, and the supply concentration was controlled by the proportion with respect to the TMG supply rate.

An n-clad layer/MQW/p-clad layer/p-GaN layer was further grown. The carrier gas was switched to nitrogen.

The multilayer structure was produced by layering a 25 nm AlN single crystal seed layer on a substrate composed of a sapphire C-plane ((0001) crystal plane), layering thereover a luminescent layer having a multiple quantum structure comprising an undoped GaN ground layer (film thickness=6 μm), an Si-doped n-type GaN contact layer (film thickness=2 μm), an Si-doped n-type In_{0.01}Ga_{0.99}N clad layer (film thickness=50 nm), a 6-layer Si-doped GaN barrier layer (film thickness=14.0 nm) and a 5-layer undoped In_{0.08}Ga_{0.92}N well layer (layer thickness

=2.5 nm), and then a Mg-doped p-type Al_{0.07}Ga_{0.93}N clad layer (layer thickness=10 nm) and a Mg-doped p-type GaN contact layer (layer thickness=150 nm).

Upon completion of vapor growth of the contact layer composed of the Mg-doped AlGaN layer, the carrier gas was immediately switched from H₂ to N₂, the flow rate of NH₃ was reduced and the flow rate of the carrier gas nitrogen was increased by the amount of this reduction. Specifically, the NH₃ constituting 50% of the total circulating gas volume during growth was reduced to 0.2%. At the same time, supply of electricity to the high-frequency induction heating system used for heating of the substrate was interrupted.

The rocking curve half-widths of the p-GaN contact layer were 45 arcsec and 215 arcsec on the (0002) plane and (10-10) plane, respectively.

### (3) LED Chip

An LED chip was fabricated using an epitaxial multilayer structure wafer provided with the aforementioned p-type contact layer. First, an anode composed of ITO was formed on the p-type contact layer by sputtering. The following procedure was then followed to form a conductive translucent oxide electrode layer made of ITO on a gallium nitride-based compound semiconductor.

A known photolithography technique and etching technique were used first to form a conductive translucent oxide electrode layer made of ITO on a p-type AlGaN contact layer. For formation of the conductive translucent oxide electrode layer, first a substrate layered with a gallium nitride-based compound semiconductor was placed in a sputtering apparatus, and after first forming ITO on the p-type AlGaN contact layer to approximately 2 nm by RF sputtering, ITO was layered thereover to approximately 400 nm by DC sputtering. The pressure during RF film formation was approximately 0.3 Pa and the power supply was 0.5 kW. The pressure during DC film formation was approximately 0.8 Pa and the power supply was 1.5 kW.

After forming the ITO film, it was subjected to annealing treatment for 1 minute at 500° C. in a nitrogen atmosphere containing 20% oxygen.

Upon completion of annealing treatment, ordinary dry etching was carried out on the region on which a cathode was to be formed, and the surface of the Si-doped n-type GaN contact layer was exposed at this region alone.

Next, a first layer made of Cr (film thickness=40 nm), a second layer made of Ti (layer thickness=100 nm) and a third layer made of Au (film thickness=400 nm) were layered in that order on a portion of the ITO film layer and on the exposed Si-doped n-type GaN contact layer by vacuum vapor deposition, to form a cathode bonding pad layer and anode bonding pad layer.

After forming the cathode bonding pad layer and anode bonding pad layer, the back side of the sapphire substrate was shaved off by grinding to 120 μm using a diamond grinding stone, and a diamond particle abrasive was used for polishing to obtain a mirror surface finish with a final thickness of 80 μm. Next, the multilayer structure was cut and separated into discrete 350 μm square LEDs. The structure of the obtained LED is shown in FIG. 2.

Next, chips were bonded to a simple measuring lead frame (TO-18) using an epoxy adhesive, and the anode and cathode were each connected to the lead frame with gold (Au) wires.

A forward current was applied between the anode and cathode of an LED chip mount fabricated by these steps, and the electrical and luminescent characteristics were evaluated. The results are shown below.

If (DC forward current) 20 mA; Vf (1 μA)(DC forward voltage) 2.33 V; Vf (20 ma)(driving voltage) 3.03 V; Ir (20 V)(DC reverse current) 0.05 μA; Vr (10 μA)(DC reverse voltage) 20 V; Pₒ (luminous output measured with integrating sphere) 17.2 mW; λd (luminous wavelength) 459 nm

From a wafer with a diameter of 100 mm there were obtained approximately 50,000 LEDs, ignoring those with apparent defects.

### (4) Package

Next, a chip was bonded to a top view package lead frame using an epoxy adhesive, and the anode and cathode were each connected to the lead frame with gold (Au) wires. It was then sealed with an epoxy resin sealing compound.

A forward current was applied between the anode and cathode of the top view package fabricated in this step, and satisfactory electrical and luminescent characteristics were exhibited.

### Example 2

A GaN-based semiconductor multilayer structure was fabricated using an AlN seed layer (12) obtained in the same manner as Example 1. The growing conditions for the GaN-based semiconductor layer by MOCVD were as follows.

### (A: Ground Layer (Undoped GaN))

Total gas pressure: 400 mbar; susceptor temperature: 1100° C.; H₂ flow rate: 30 slm; N₂ flow rate: 0 slm; TMG flow rate: 300 sccm; NH₃ flow rate: 7 slm; SiH₄ flow rate: 0 sccm

(B: n-Contact Layer (n-GaN))

Total gas pressure: 400 mbar; susceptor temperature: 1100° C.; H₂ flow rate: 30 slm; N₂ flow rate: 0 slm; TMG flow rate: 300 sccm; NH₃ flow rate: 7 slm; SiH₄ flow rate: 120 sccm

(C: n-Clad Layer)

Total gas pressure: 400 mbar; susceptor temperature: 760° C.; H₂ flow rate: 0 slm; N₂ flow rate: 50 slm; TMG flow rate: 0 sccm; TEG flow rate: 250 sccm; TMA flow rate: 0 sccm; NH₃ flow rate: 18 slm; TMI flow rate: 20 sccm; SiH₄ flow rate: 50 sccm; Cp₂Mg flow rate: 0 sccm

### (D: Luminescent Layer)

Total gas pressure: 400 mbar; susceptor temperature: 760/960° C.; H₂ flow rate: 0 slm; N₂ flow rate: 50 slm; TMG flow rate: 0 sccm; TEG flow rate: 150 sccm; TMA flow rate: 0 sccm; NH₃ flow rate: 18 slm; TMI flow rate: 480/0 sccm; SiH₄ flow rate: 0/30 sccm; Cp₂Mg flow rate: 0 sccm

(E: p-Clad Layer)

Total Gas Pressure: 400 Mbar; Susceptor Temperature: 1020° C.; H₂ flow rate: 30 slm; N₂ flow rate: 0 slm; TMG flow rate: 180 sccm; TEG flow rate: 0 sccm; TMA flow rate: 100 sccm; NH₃ flow rate: 21 slm; TMI flow rate: 0 sccm; SiH₄ flow rate: 0 sccm; Cp₂Mg flow rate: 150 sccm

(F: p-Contact Layer)

Total Gas Pressure: 400 Mbar; Susceptor Temperature: 1040° C.; H₂ flow rate: 30 slm; N₂ flow rate: 0 slm; TMG flow rate: 180 sccm; TEG flow rate: 0 sccm; TMA flow rate: 0 sccm; NH₃ flow rate: 21 slm; TMI flow rate: 0 sccm; SiH₄ flow rate: 0 sccm; Cp₂Mg flow rate: 300 sccm

The growth speed was 2 μm/hr for each layer.

The obtained multilayer structure was used to fabricate an LED chip by the same method as Example 1. The rocking curve half-widths of the p-GaN contact layer were 49 arcsec and 225 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.34 V; Vf (20 mA)(driving voltage) 3.12 V; Ir (20 V)(DC reverse current) 0.06 μA; Vr (10 μA)(DC reverse voltage) 20 V; Pₒ (luminous output measured with integrating sphere) 8.2 mW; kd (luminous wavelength) 525 nm

### Example 3

An LED chip was fabricated by the same method as Example 1, except that the heater temperature was 300° C. for plasma treatment of the sapphire substrate. The properties of the obtained AlN seed film were as follows.

Ra: 1.7 angstrom, oxygen concentration: 3.1 atomic percent, FWHM (0002): 45 arcsec, FWHM (10-10): 1.5 degrees

The rocking curve half-widths of the p-GaN contact layer were 53 arcsec and 230 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.34 V; Vf (20 mA)(driving voltage) 3.03 V; Ir (20 V)(DC reverse current) 0.13 μA; Vr (10 μA)(DC reverse voltage) 20 V; Pₒ (luminous output measured with integrating sphere) 16.8 mW; λd (luminous wavelength) 460 nm

### Example 4

An LED chip was fabricated by the same method as Example 1, except that the heater temperature was 950° C. for plasma treatment of the sapphire substrate. The properties of the obtained AlN seed film were as follows.

Ra: 1.6 angstrom, oxygen concentration: 2.9 atomic percent, FWHM (0002): 47 arcsec, FWHM (10-10): 1.5 degrees

The rocking curve half-widths of the p-GaN contact layer were 59 arcsec and 245 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.31 V; Vf (20 mA)(driving voltage) 3.02 V; Ir (20 V)(DC reverse current) 0.16 μA; Vr (10 μA)(DC reverse voltage) 20 V; Pₒ (luminous output measured with integrating sphere) 16.9 mW; λd (luminous wavelength) 460 nm

### Example 5

An LED chip was fabricated by the same method as Example 1, except that the film-forming temperature for the AlN seed layer was 400° C. The properties of the obtained AlN seed film were as follows.

Ra: 1.4 angstrom, oxygen concentration: 2.9 atomic percent, FWHM (0002): 35 arcsec, FWHM (10-10): 1.5 degrees

The rocking curve half-widths of the p-GaN contact layer were 45 arcsec and 223 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.34 V; Vf (20 mA)(driving voltage) 3.01 V; Ir (20 V)(DC reverse current) 0.08 HA; Vr (10 μA)(DC reverse voltage) 20 V; Pₒ (luminous output measured with integrating sphere) 16.9 mW; kd (luminous wavelength) 460 nm

### Example 6

An LED chip was fabricated by the same method as Example 1, except that the film-forming temperature for the AlN seed layer was 800° C. The properties of the obtained AlN seed film were as follows.

Ra: 1.6 angstrom, oxygen concentration: 3.4 atomic percent, FWHM (0002): 36 arcsec, FWHM (10-10): 1.5 degrees

The rocking curve half-widths of the p-GaN contact layer were 46 arcsec and 233 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.34 V; Vf (20 mA)(driving voltage) 3.02 V; Ir (20 V)(DC reverse current) 0.07 μA; Vr (10 μA)(DC reverse voltage) 20 V; Pₒ (luminous output measured with integrating sphere) 17.0 mW; % d (luminous wavelength) 459 nm

### Example 7

An LED chip was fabricated by the same method as Example 1, except that the TS distance was 80 mm. The properties of the obtained AlN seed film were as follows.

Ra: 1.7 angstrom, oxygen concentration: 3.5 atomic percent, FWHM (0002): 32 arcsec, FWHM (10-10): 1.4 degrees

The rocking curve half-widths of the p-GaN contact layer were 48 arcsec and 225 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.32 V; Vf (20 mA)(driving voltage) 3.03 V; Ir (20 V)(DC reverse current) 0.03 μA; Vr (10 μA)(DC reverse voltage) 20 V; Pₒ (luminous output measured with integrating sphere) 17.1 mW; % d (luminous wavelength) 459 nm

### Example 8

An LED chip was fabricated by the same method as Example 1, except that the film-forming time was 150 seconds. The properties of the obtained AlN seed film were as follows.

Ra: 1.9 angstrom, oxygen concentration: 3.3 atomic percent, FWHM (0002): 42 arcsec, FWHM (10-10): 1.6 degrees

The rocking curve half-widths of the p-GaN contact layer were 50 arcsec and 240 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.34 V; Vf (20 mA)(driving voltage) 3.02 V; Ir (20 V)(DC reverse current) 0.06 μA; Vr (10 μA)(DC reverse voltage) 20 V; Pₒ (luminous output measured with integrating sphere) 16.5 mW; λd (luminous wavelength) 460 nm

### Example 9

An LED chip was fabricated by the same treatment as Example 1, except that substrate cleaning was not performed because 7 days had not elapsed since abrasive finishing of the substrate. The properties of the obtained AlN seed film were as follows.

Ra: 1.9 angstrom, oxygen concentration: 3.3 atomic percent, FWHM (0002): 34 arcsec, FWHM (10-10): 1.4 degrees

The rocking curve half-widths of the p-GaN contact layer were 46 arcsec and 218 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.32 V; Vf (20 mA)(driving voltage) 3.02 V; Ir (20 V)(DC reverse current) 0.05 μA; Vr (10 μA)(DC reverse voltage) 20 V; Pₒ (luminous output measured with integrating sphere) 17.1 mW; λd (luminous wavelength) 459 nm

### Comparative Example 1

An LED chip was fabricated by the same method as Example 1, except that the base pressure was 4×10⁻⁴ Pa for the AlN growth conditions. The properties of the obtained AlN seed film were as follows.

Ra 4.5 angstrom, oxygen concentration: 6.7 atomic percent, FWHM (0002): 163 arcsec, FWHM (10-10): 1.9 degrees

The rocking curve half-widths of the p-GaN contact layer were 72 arcsec and 312 arcsec on the (0002) plane and (10-10) plane, respectively.

A forward current was applied between the anode and cathode and the electrical and luminescent characteristics were evaluated, in the same manner as Example 1. The results are shown below.

If (DC forward current) 20 mA; Vf (1 μA)(DC forward voltage) 2.12 V; Vf (20 mA)(driving voltage) 3.13 V; Ir (20 V)(DC reverse current) 0.36 μA; Vr (10 μA)(DC reverse voltage) 20 V; Pₒ (luminous output measured with integrating sphere) 14.9 mW; kd (luminous wavelength) 468 nm

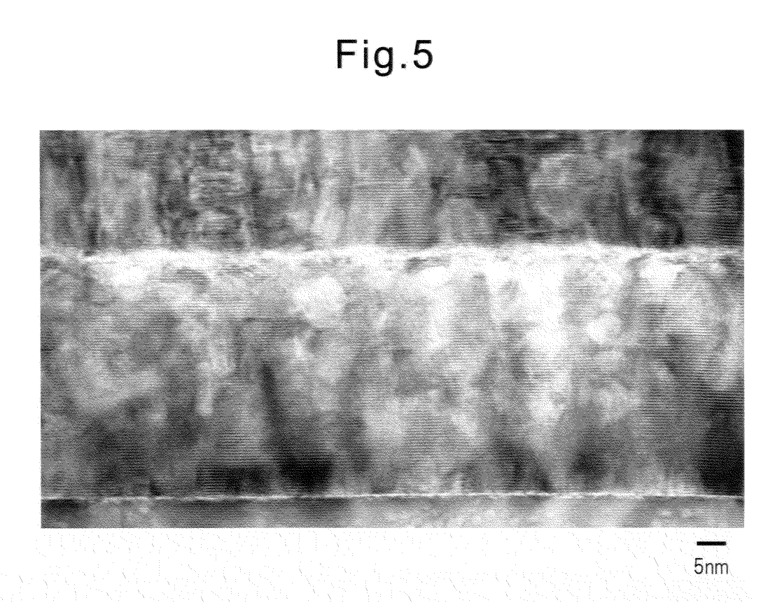

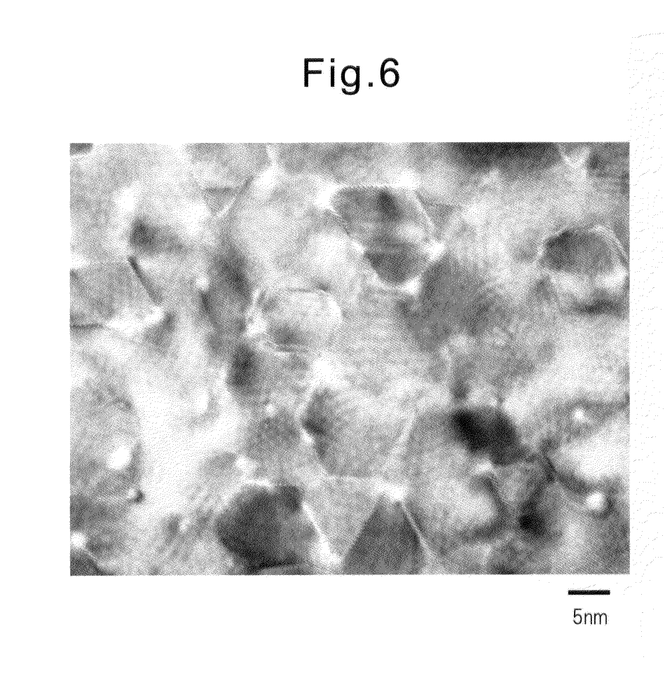

FIG. 5 and FIG. 6 show, respectively longitudinal cross-section TEM and planar surface TEM photographs of the seed layer of the obtained AlN crystal film. The three layers seen in FIG. 5 are, from the bottom, the sapphire substrate, the AlN crystal film seed layer and the GaN ground layer. As in FIG. 3 and FIG. 4, observation was made with shifting of the visual field. As a result, grain boundaries were observed in a 200 nm observation field and in a 200 nm square observation field. Specifically, characteristic density variation in the lattice image was seen in the columnar crystals in the longitudinal cross-section TEM photograph. On the other hand, hexagonal grain boundaries were seen in the planar surface TEM photograph, and columnar crystals were observed.

According to the invention it is possible to obtain a flat AlN crystal film seed layer with a high degree of crystallinity, and particularly, a flat AlN crystal film seed layer that is homogeneous throughout can be used even with large substrates having diameters of 100 mm and greater, in order to obtain highly crystalline GaN-based thin-films for highly reliable, high-luminance LED elements and the like.

What is claimed is:

1. A Group III nitride semiconductor multilayer structure obtained by layering an n-type semiconductor layer, composed of a Group III nitride semiconductor, a luminescent layer and a p-type semiconductor layer, on a sapphire substrate, the Group III nitride semiconductor multilayer structure being characterized by having an AlN crystal film that is accumulated as the seed layer by sputtering on the sapphire substrate surface, the AlN crystal film having a grain boundary spacing of 200 nm or greater.

2. The Group III nitride semiconductor multilayer structure according to claim 1, wherein the arithmetic mean surface roughness (Ra) of the AlN crystal film surface is no greater than 2 angstrom.

3. The Group III nitride semiconductor multilayer structure according to claim 1, wherein the rocking curve half-widths in X-ray diffraction for the (0002) plane and (10-10) plane of the AlN crystal film are no greater than 100 arcsec and no greater than 1.7 degrees, respectively.

4. The Group III nitride semiconductor multilayer structure according to claim 1, wherein the oxygen content of the AlN crystal film is no greater than 5 atomic percent.

5. The Group III nitride semiconductor multilayer structure according to claim 1, wherein the sapphire substrate is a C-plane sapphire substrate.

6. The Group III nitride semiconductor multilayer structure according to claim 1, wherein the sapphire substrate has an off-angle of 0.1-0.7 degrees.

7. The Group III nitride semiconductor multilayer structure according to claim 1, wherein the sputtering method is RF sputtering.

8. The Group III nitride semiconductor multilayer structure according to claim 1, wherein the AlN crystal film is accumulated by sputtering with the sapphire substrate situated in plasma.

9. The Group III nitride semiconductor multilayer structure according to claim 1, wherein the AlN crystal film is accumulated on the sapphire substrate surface after the sapphire substrate surface has been treated with N₂ plasma or O₂ plasma.

10. The Group III nitride semiconductor multilayer structure according to claim 1, wherein the substrate temperature during accumulation of the AlN crystal film on the sapphire substrate surface is 300-800° C.

11. The Group III nitride semiconductor multilayer structure according to claim 1, wherein the film thickness of the AlN crystal film is 10-50 nm.

12. The Group III nitride semiconductor multilayer structure according to claim 11, wherein the film thickness of the AlN crystal film is 25-35 nm.

13. The Group III nitride semiconductor multilayer structure according to claim 1, wherein the diameter of the sapphire substrate is 100 mm or greater.

14. The Group III nitride semiconductor multilayer structure according to claim 1, wherein the rocking curve half-widths of the p-contact layer as the final p-type semiconductor layer are no greater than 60 arcsec and no greater than 250 arcsec for the (0002) plane and (10-10) plane, respectively.

15. A light emitting device comprising a Group III nitride semiconductor multilayer structure according to claim 1.

16. The light emitting device according to claim 15, wherein a cathode is provided on the n-type semiconductor layer and an anode is provided on the p-type semiconductor layer.

17. A production method for a Group III nitride semiconductor multilayer structure, characterized in that, for production of a Group III nitride semiconductor multilayer structure obtained by layering an n-type semiconductor layer, composed of a Group III nitride semiconductor, a luminescent layer and a p-type semiconductor layer, on a sapphire substrate, an AlN crystal film having a grain boundary spacing of 200 nm or greater is formed as the seed layer by sputtering on the sapphire substrate surface, while controlling the oxygen content to no greater than 5 atomic percent.

18. The production method for a Group III nitride semiconductor multilayer structure according to claim 17, wherein the center line surface roughness (Ra) of the AlN crystal film surface is no greater than 2 angstrom.

19. The production method for a Group III nitride semiconductor multilayer structure according to claim 17, wherein the rocking curve half-widths in X-ray diffraction for the (0002) plane and (10-10) plane of the AlN crystal film are no greater than 100 arcsec and no greater than 1.7 degrees, respectively.

20. The production method for a Group III nitride semiconductor multilayer structure according to claim 17, wherein the sapphire substrate is a C-plane sapphire substrate.

21. The production method for a Group III nitride semiconductor multilayer structure according to claim 17, wherein the sapphire substrate has an off-angle of 0.1-0.7 degrees.

22. The production method for a Group III nitride semiconductor multilayer structure according to claim 17, wherein the sputtering method is RF sputtering.

23. The production method for a Group III nitride semiconductor multilayer structure according to claim 17, wherein the AlN crystal film is accumulated by sputtering with the sapphire substrate situated in plasma.

24. The production method for a Group III nitride semiconductor multilayer structure according to claim 17, wherein the AlN crystal film is formed under conditions in which no oxygen-attributed peak is seen in gas analysis during plasma discharge, to obtain an AlN crystal film with an oxygen content of no greater than 5 atomic percent.

25. The production method for a Group III nitride semiconductor multilayer structure according to claim 17, wherein the AlN single-crystal film is accumulated on the sapphire substrate surface after the sapphire substrate surface has been treated with N₂ plasma or O₂ plasma.

26. The production method for a Group III nitride semiconductor multilayer structure according to claim 17, wherein the substrate temperature during accumulation of the AlN crystal film on the sapphire substrate surface is 300-800° C.

27. The production method for a Group III nitride semiconductor multilayer structure according to claim 17, wherein the film thickness of the AlN crystal film is 10-50 nm.

28. The production method for a Group III nitride semiconductor multilayer structure according to claim 27, wherein the film thickness of the AlN crystal film is 25-35 nm.

29. The production method for a Group III nitride semiconductor multilayer structure according to claim 17, wherein the diameter of the sapphire substrate is 100 mm or greater.

30. A lamp comprising a light emitting device according to claim 16.

31. An electronic device incorporating a lamp according to claim 30.

32. A machine incorporating an electronic device according to claim 31.
